(19) United States
(12) Patent Application Publication
(10) Pub. No.: US 2024/0324416 A1
(43) Pub. Date: Sep. 26, 2024

(54) DISPLAY PANEL AND ELECTRONIC DEVICE COMPRISING THE SAME

(71) Applicant: Samsung Display Co., Ltd., Yongin-si (KR)

(72) Inventors: Woongsik Kim, Yongin-si (KR); Jinsu Byun, Yongin-si (KR); Sikwang Kim, Yongin-si (KR); Jungmin Choi, Yongin-si (KR)

(73) Assignee: Samsung Display Co., Ltd., Yongin-si (KR)

(21) Appl. No.: 18/594,509

(22) Filed: Mar. 4, 2024

(30) Foreign Application Priority Data
Mar. 24, 2023 (KR) 10-2023-0039053
Apr. 11, 2023 (KR) 10-2023-0047578

(51) Int. Cl. H10K 59/80

(52) U.S. Cl. CPC H10K 59/879; H10K 59/873

(57) ABSTRACT

A display panel including a pixel layer including first to third display elements, which emit light of different colors, an encapsulation member for sealing the pixel layer, a first refractive layer disposed on the encapsulation member and including a first opening overlapping the second display element, and a second refractive layer disposed on the first refractive layer to cover the first refractive layer, and having a refractive index different from a refractive index of the first refractive layer, wherein a distance between an upper surface of the substrate and a lower surface of the second refractive layer, in an area overlapping the second display element, is smaller than a distance between the upper surface of the substrate and the lower surface of the second refractive layer, in an area overlapping the third display element.

### CROSS-REFERENCE TO RELATED APPLICATION(S)

This application claims priority to and the benefits of Korean Patent Application Nos. 10-2023-0039053, filed on Mar. 24, 2023 in the Korean Intellectual Property Office, and 10-2023-0047578, filed on Apr. 11, 2023 in the Korean Intellectual Property Office, the entire contents of which are herein incorporated by reference.

### BACKGROUND

### 1. Technical Field

One or more embodiments relate to a display panel with excellent emission efficiency and an electronic device including the display panel.

### 2. Description of the Related Art

As demands for display devices have increased, a need for display devices that may be used for various purposes has also increased. According to this trend, display devices have tended to become larger or thinner, and a need for display devices having accurate and vivid colors while becoming larger and thinner has also increased.

### SUMMARY

One or more embodiments include a display panel with improved side optical characteristics and improved light efficiency, and an electronic device including the display panel. However, these are only examples, and the scope of the disclosure is not limited thereto.

Additional aspects will be set forth in part in the description that follows and, in part, will be apparent from the description, or may be learned by practice of the embodiments of the disclosure.

According to one or more embodiments, a display panel may include a pixel layer disposed on a substrate, the pixel layer including a first display element, a second display element, and a third display element, which emit light of different colors, an encapsulation member for sealing the pixel layer, a first refractive layer disposed on the encapsulation member and including a first opening overlapping the second display element, and a second refractive layer disposed on the first refractive layer to overlap the first refractive layer, and having a refractive index different from a refractive index of the first refractive layer, wherein a distance between an upper surface of the substrate and a lower surface of the second refractive layer, in an area overlapping the second display element, is smaller than a distance between the upper surface of the substrate and the lower surface of the second refractive layer, in an area overlapping the third display element.

The display panel may further include a first lower refractive pattern disposed between the encapsulation member and the first refractive layer, in an area overlapping the first display element, wherein the first lower refractive pattern may have a refractive index different from the refractive index of the first refractive layer.

The refractive index of the first lower refractive pattern may be lower than the refractive index of the first refractive layer, and the refractive index of the second refractive layer may be lower than the refractive index of the first refractive layer.

The refractive index of the first lower refractive pattern may be higher than the refractive index of the first refractive layer, and the refractive index of the second refractive layer may be higher than the refractive index of the first refractive layer.

The refractive index of the first lower refractive pattern and the refractive index of the second refractive layer may be equal.

The display element may further include a second lower refractive pattern disposed between the first refractive layer and the encapsulation member, in the area overlapping the third display element.

The first refractive layer may include a second opening in the area overlapping the third display element, and a refractive pattern may be further included in the second opening.

The refractive pattern and the first refractive layer may include the same material.

A distance between an upper surface of the refractive pattern and an upper surface of the encapsulation member may be equal to a distance between an upper surface of the first refractive layer and the upper surface of the encapsulation member.

The display panel may further include a first lower refractive pattern disposed between the encapsulation member and the first refractive layer, in an area corresponding to the first display element, wherein the first lower refractive pattern may have a refractive index different from the refractive index of the first refractive layer.

The first refractive layer may further include a third opening in an area corresponding to the first display element.

The second refractive layer may be disposed to fill the first opening of the first refractive layer.

The refractive index of the second refractive layer may be lower than the refractive index of the first refractive layer.

The refractive index of the second refractive layer may be higher than the refractive index of the first refractive layer.

The display panel may further include an input sensing layer between the encapsulation member and the first refractive layer, the input sensing layer including a sensing electrode.

According to one or more embodiments, a display panel may include a pixel layer disposed on a substrate and including a display element emitting light, an encapsulation member for sealing the pixel layer, a first refractive layer disposed on the encapsulation member and disposed in an area overlapping the display element, a lower refractive pattern disposed between the encapsulation member and the first refractive layer, in the area overlapping the display element, the lower refractive pattern having a refractive index different from a refractive index of the first refractive layer, and a second refractive layer disposed on the encapsulation member to overlap the first refractive layer, the second refractive layer having a refractive index different from the refractive index of the first refractive layer.

The refractive index of the lower refractive pattern may be lower than the refractive index of the first refractive layer, and the refractive index of the second refractive layer may be lower than the refractive index of the first refractive layer.

The refractive index of the lower refractive pattern may be higher than the refractive index of the first refractive layer, and the refractive index of the second refractive layer may be higher than the refractive index of the first refractive layer.

The refractive index of the lower refractive pattern and the refractive index of the second refractive layer may be equal.

According to one or more embodiments, an electronic device may include a display panel, a cover window disposed on the display panel, and a housing accommodating the display panel and the cover window. The display panel may include a pixel layer disposed on a substrate, the pixel layer including a first display element, a second display element, and a third display element, which emit light of different colors, an encapsulation member for sealing the pixel layer, a first refractive layer disposed on the encapsulation member and including a first opening overlapping the second display element, and a second refractive layer disposed on the first refractive layer to overlap the first refractive layer, and having a refractive index different from a refractive index of the first refractive layer, wherein a distance between an upper surface of the substrate and a lower surface of the second refractive layer, in an area overlapping the second display element is smaller than a distance between the upper surface of the substrate and the lower surface of the second refractive layer, in an area overlapping the third display element.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view illustrating a portion of an electronic device according to an embodiment;

FIG. 2 is a schematic cross-sectional view taken along line I-I′ in FIG. 1.

FIG. 3 is a schematic diagram illustrating a portion of a display panel according to an embodiment;

FIGS. 4A and 4B are schematic diagrams illustrating examples of a pixel according to an embodiment;

FIG. 5 is a partial schematic plan view illustrating an arrangement of a pixel according to an embodiment;

FIG. 6 is a schematic cross-sectional view taken along line II-II′ in FIG. 5;

FIG. 7 is a partial schematic plan view illustrating a portion of a refractive layer according to an embodiment;

FIGS. 8A and 8B are schematic cross-sectional views taken along line III-III′ in FIG. 7;

FIG. 9 is a partial schematic plan view illustrating a portion of a refractive layer according to another embodiment;

FIGS. 10A and 10B are schematic cross-sectional views taken along line IV-IV′ in FIG. 9;

FIG. 11 is a partial schematic plan view illustrating a portion of a refractive layer according to another embodiment;

FIG. 12 is a schematic cross-sectional view taken along line V-V′ in FIG. 11;

FIG. 13 is a partial schematic plan view illustrating a portion of a refractive layer according to another embodiment;

FIG. 14 is a schematic cross-sectional view taken along line VI-VI′ in FIG. 13;

FIG. 15 is a schematic cross-sectional view taken along line I-I′ in FIG. 1, according to another embodiment; and

FIG. 16 is a schematic partial cross-sectional view of a display panel according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that when a layer, region, or element is referred to as being “on” another layer, region, or element, it can be directly or indirectly on the other layer, region, or element. That is, for example, intervening layers, regions, or elements may be present. Sizes of elements in the drawings may be exaggerated or reduced for convenience of explanation.

It will be understood that when a layer, region, or element is referred to as being “connected” to another layer, region, or element, it may be “directly connected” to the other layer, region, or element or may be “indirectly connected” to the other layer, region, or element with other layer, region, or element therebetween.

It will be understood that the terms “connected to” or “coupled to” may include a physical and/or electrical connection or coupling.

When an embodiment may be implemented differently, a certain process order may be performed differently from the described order. For example, two consecutively described processes may be performed substantially at the same time or performed in an order opposite to the described order.

In an embodiment below, terms, such as “first” and “second,” are used herein merely to describe a variety of elements, but the elements are not limited by the terms. Such terms are used only for the purpose of distinguishing one element from another element.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the following disclosure, it will be understood that when a line is referred to as “extending in a first direction or a second direction,” it cannot only extend in a linear shape, but also can extend in the first direction or the second direction in a zigzag or curved line.

In the following embodiments, when referred to “in a plan view,” it means when an object is viewed from above, and when referred to “in a cross-sectional view,” it means when a cross section formed by vertically cutting an object is viewed from the side.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

In the following embodiments, a signal is a generic term for voltage or current unless otherwise specified. In the following embodiments, “C,” a sign used as a symbol for a capacitor, is used as a sign for a capacitor and also indicates capacitance, which is a size of the capacitor. Both self-made capacitor and naturally formed capacitors are referred to as capacitors without distinction.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

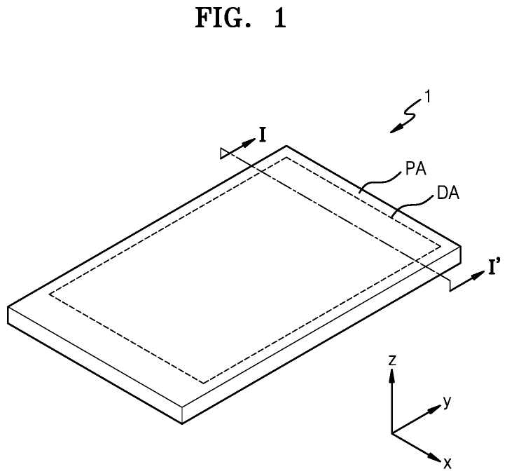

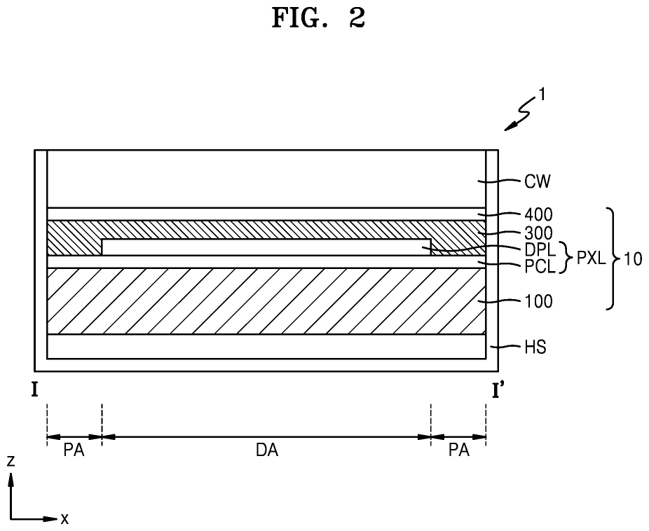

FIG. 1 is a schematic perspective view illustrating a portion of an electronic device 1 according to an embodiment. FIG. 2 is a schematic cross-sectional view taken along line I-I′ in FIG. 1.

Referring to FIG. 1, the electronic device 1 according to an embodiment may include a display area DA and a peripheral area PA. The peripheral area PA may be arranged outside the display area DA to surround the display area DA. Various lines for transferring electrical signals to be applied to the display area DA, and a driving circuit unit may be located in the peripheral area PA. The electronic device 1 may provide an image by using light emitted from pixels arranged in the display area DA. Although not shown, the electronic device 1 may include a bending area in a partial area of the peripheral area PA, and may be bent.

The electronic device 1, which is a device for displaying a moving image or a still image, may be used in not only portable electronic devices, such as mobile phones, smartphones, tablet personal computers (PCs), mobile communication terminals, electronic notebooks, electronic books, portable multimedia players (PMPs), navigations, and ultra mobile PCs (UMPCs), but also various products, such as televisions, laptops, monitors, billboards, and Internet of Things (IoT) devices. The electronic device according to an embodiment may be used in wearable devices, such as smart watches, watch phones, glasses-type displays, and head-mounted displays (HMDs).

The electronic device 1 may be a display device, such as organic light-emitting displays, inorganic light-emitting displays (or an inorganic electroluminescent (EL) display devices), or quantum dot light-emitting displays.

As shown in FIG. 2, the electronic device 1 may include a housing HS, a display panel 10, and a cover window CW.

The housing HS may accommodate the display panel 10. The housing HS may accommodate the display panel 10 and the cover window CW on the display panel 10. Although it is shown that the housing HS surrounds edges of the display panel 10 and the cover windows CW in an integral manner, one or more embodiments are not limited thereto. In an embodiment, the housing HS may have a shape in which two or more members are coupled together rather than integrally formed. In addition to the display panel 10 and the cover window CW, components necessary for driving of the electronic device 1, for example, a power unit, such as a battery, or a circuit board may be mounted inside the housing HS.

The display panel 10 may include the display area DA and the peripheral area PA outside the display area DA. The display panel 10 may provide an image through an array of pixels arranged in the display area DA. The display panel 10 may be disposed under the housing HS. The display panel 10 may be disposed under the cover window CW.

The display panel 10 may include a substrate 100 and an encapsulation member 300 for sealing the substrate 100, which are sequentially stacked on each other in a third direction (z direction).

The substrate 100 may include a glass material and/or a polymer resin. For example, the substrate 100 may include a glass material with silicon oxide (SiO₂) as a main component, or may include various materials having flexible or bendable properties, such as a resin, such as reinforced plastic. Although not shown, the substrate 100 may include a bending area in a partial area of the peripheral area PA, and may be bent.

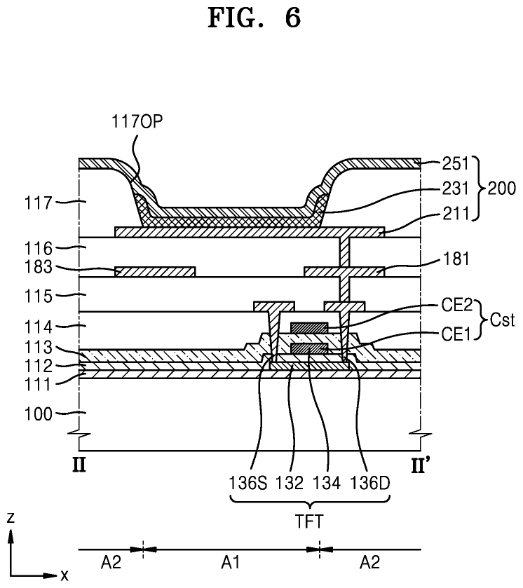

The display panel 10 may include a pixel layer PXL. The pixel layer PXL may be disposed on the substrate 100. The pixel layer PXL may include a display element layer DPL including display elements arranged for each pixel, and a pixel circuit layer PCL including pixel circuits and insulating layers arranged for each pixel. For example, the pixel circuit layer PCL may be a layer including a thin-film transistor TFT, a capacitor Cst, and insulating layers shown in FIG. 6. For example, the display element layer DPL may be a layer including an organic light-emitting diode 200 in FIG. 6, as a display element. Although it is described below that the electronic device 1 includes an organic light-emitting diode as a display element, one or more embodiments are not limited thereto. In an embodiment, the display element may be a light-emitting diode including an inorganic material, or may be a quantum dot light-emitting diode including quantum dots. The display element layer DPL may be disposed on an upper layer of the pixel circuit layer PCL, and insulating layers may be arranged between the pixel circuit and the display element. At least a subset of lines and insulating layers of the pixel circuit layer PCL may each extend to the peripheral area PA.

The encapsulation member 300 may seal the pixel layer PXL and may be disposed on the pixel layer PXL. The encapsulation member 300 may be a thin-film encapsulation layer. The thin-film encapsulation layer may include at least one inorganic encapsulation layer and at least one organic encapsulation layer. In case that the display panel 10 has a substrate 100 including a polymer resin, and an encapsulation member 300 of a thin-film encapsulation layer including an inorganic encapsulation layer and an organic encapsulation layer, flexibility of the electronic device 1 may be improved.

The display panel 10 may include a refractive layer 400 over the encapsulation member 300. The refractive layer 400 may adjust a path of light emitted from the display element of the display element layer DPL and serve as a lens. The refractive layer 400 may change the passage of the light emitted from the display element, so as to improve color shifts of light emitted to the front of the electronic device 1 and light emitted to a side surface of the electronic device 1, and improve light extraction efficiency from the front.

The cover window CW may be disposed on the display panel 10. The cover window CW may be disposed over the housing HS. In an embodiment, the cover window CW may include glass and/or polymer resin. In an embodiment, the cover window CW may include polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. In an embodiment, the cover window CW may include ultra-thin tempered glass (UTG), of which a strength is enhanced by a method, such as chemical strengthening or thermal strengthening. For example, the refractive layer 400 may be provided between the encapsulation member 300 and a polarizing plate.

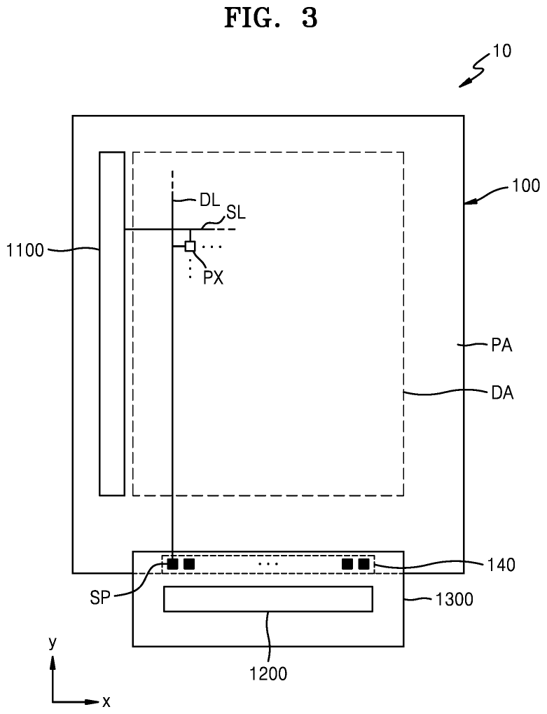

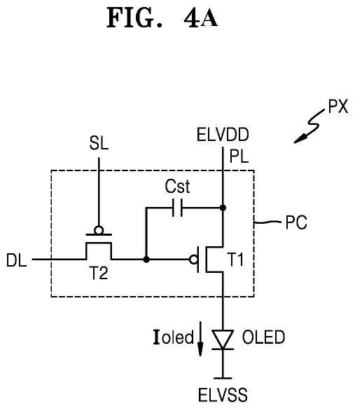

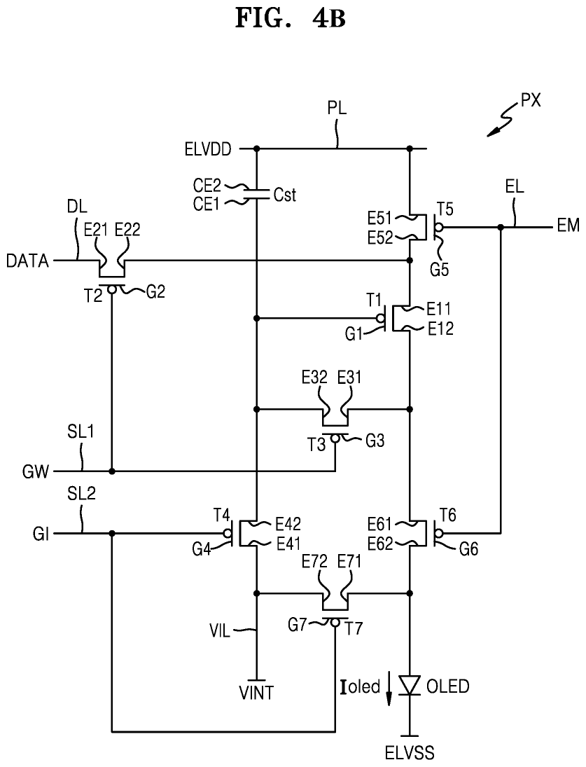

FIG. 3 is a schematic diagram illustrating a portion of the display panel 10 according to an embodiment. FIGS. 4A and 4B are schematic diagrams illustrating examples of a pixel according to an embodiment.

Referring to FIG. 3, the substrate 100 may include the display area DA and the peripheral area PA. The peripheral area PA may be located outside the display area DA and may surround the display area DA.

In the display area DA on the substrate 100, pixels PX arranged in a pattern in a first direction (x direction; row direction) and a second direction (y direction; column direction) may be provided.

In the peripheral area PA on the substrate 100, a scan driver 1100 for providing a scan signal to each of the pixels PX, a data driver 1200 for providing a data signal to each of the pixels PX, main power lines (not shown) for providing a first power voltage ELVDD (see FIGS. 4A and 4B) and a second power voltage ELVSS (see FIGS. 4A and 4B), etc. may be arranged. In the peripheral area PA on the substrate 100, a pad unit 140 in which signal pads SP connected to a data line DL are arranged may be located.

The scan driver 1100 may include an oxide semiconductor TFT gate driver circuit (OSG) or an amorphous silicon TFT gate driver circuit (ASG). In FIG. 3, the scan driver 1100 is arranged to be adjacent to one side of the substrate 100. However, in some embodiments, the scan driver 1100 may be arranged to be adjacent to two sides of the substrate 100 facing each other.

FIG. 3 shows a chip on film (COF) type, in which the data driver 1200 may be disposed on a film 1300 electrically connected to the signal pads SP disposed on the substrate 100. According to another embodiment, the data driver 1200 may be disposed directly on the substrate 100 by a chip on glass (COG) or chip on plastic (COP) method. The data driver 1200 may be electrically connected to a flexible printed circuit board (FPCB).

Referring to FIG. 4A, the pixel PX may include a pixel circuit PC connected to a scan line SL and the data line DL, and a display element connected to the pixel circuit PC. The pixel circuit PC may include a transistor and a capacitor, and the display element may include an organic light-emitting diode OLED (200 in FIG. 6).

The pixel circuit PC may include a first transistor T1, a second transistor T2, and a capacitor Cst. Each pixel PX may emit, for example, red, green, blue, or white light through the organic light-emitting diode OLED. The first transistor T1 and the second transistor T2 may be implemented as thin-film transistors.

The second transistor T2 may be a switching transistor and may be connected to the scan line SL and the data line DL. The second transistor T2 may transfer a data signal received via the data line DL to the first transistor T1 in response to a scan signal received via the scan line SL. The capacitor Cst may be connected to the second transistor T2 and a power voltage line PL and may store a voltage corresponding to a difference between a voltage corresponding to the data signal received from the second transistor T2 and a first power voltage ELVDD supplied to the power voltage line PL.

The first transistor T1 may be a driving transistor and may be connected to the power voltage line PL and the capacitor Cst. The first transistor T1 may control a driving current I_{oled} flowing in the organic light-emitting diode OLED from the power voltage line PL to correspond to a voltage value stored in the capacitor Cst.

The organic light-emitting diode OLED may emit light having a luminance according to the driving current I_{oled}. The organic light-emitting diode OLED may include a pixel electrode, an opposite electrode, and an emission layer between the pixel electrode and the opposite electrode. The opposite electrode of the organic light-emitting diode OLED may receive a second power voltage ELVSS.

In FIG. 4A, the pixel circuit PC includes two transistors and one capacitor. However, one or more embodiments are not limited thereto. The number of transistors and the number of capacitors may be variously modified according to a design of the pixel circuit PC.

Referring to FIG. 4B, it is shown that signal lines SL1, SL2, EL, and DL, an initialization voltage line VIL, and the power voltage line PL are provided in each pixel PX. In another embodiment, at least one of the signal lines SL1, SL2, EL, and DL, the initialization voltage line VIL, and/or the power voltage line PL may be shared among neighboring pixels.

The signal lines may include a first scan line SL1 for transferring a first scan signal GW, a second scan line SL2 for transferring a second scan signal GI, an emission control line EL for transferring an emission control signal EM, and a data line DL crossing the first scan line SL1 to transfer a data signal DATA. The second scan line SL2 may be connected to the first scan line SL1 of the next row or the previous row, and the second scan line GI may be the first scan signal GW of the next row or the previous row.

The power voltage line PL may transfer the first power voltage ELVDD to the first transistor T1, and the initialization voltage line VIL may transfer an initialization voltage VINT to the pixel PX, the initialization voltage VINT initializing the first transistor T1 and a pixel electrode.

A pixel circuit of the pixel PX may include first to seventh transistors T1 to T7 and the capacitor Cst. First electrodes E11 to E71 and second electrodes E12 to E72 in FIG. 4B may be source electrodes (source regions) or drain electrodes (drain regions) depending on a type (p-type or n-type) and/or operating condition of the transistor. The first to seventh transistors T1 to T7 may be implemented as thin-film transistors.

The first transistor T1 may include a gate electrode G1 connected to a first lower electrode CE1 of the capacitor Cst, a first electrode E11 connected to the power voltage line PL via the fifth transistor T5, and a second electrode E12 electrically connected to the pixel electrode of the organic light-emitting diode OLED. The first transistor T1 may serve as a driving transistor, and receive the data signal DATA according to a switching operation of the second transistor T2 and supply current to the organic light-emitting diode OLED.

The second transistor T2 may include a gate electrode G2 connected to the first scan line SL1, a first electrode E21 connected to the data line DL, and a second electrode E22 connected to the first electrode E11 of the first transistor T1. The second transistor T2 may be turned on in response to the first scan signal GW received via the first scan line SL1 and perform a switching operation for transmitting the data signal DATA received via the data line DL to the first electrode E11 of the first transistor T1.

The third transistor T3 may include a gate electrode G3 connected to the first scan line SL1, a first electrode E31 connected to the second electrode E12 of the first transistor T1, and a second electrode E32 connected to a lower electrode CE1 of the capacitor Cst, a second electrode E42 of the fourth transistor T4, and the gate electrode G1 of the first transistor T1. The first electrode E31 may be connected to the pixel electrode of the organic light-emitting diode OLED via the sixth transistor T6. The third transistor T3 may be turned on in response to the first scan signal GW received via the first scan line SL1, to diode-connect the first transistor T1.

The fourth transistor T4 may include a gate electrode G4 connected to the second scan line SL2, a first electrode E41 connected to the initialization voltage line VIL, and a second electrode E42 connected to the lower electrode CE1 of the capacitor Cst, the second electrode E32 of the third transistor T3, and the gate electrode G1 of the first transistor T1. The fourth transistor T4 may be turned on in response to the second scan signal GI received via the second scan line SL2 and may transfer the initialization voltage VINT to the gate electrode G1 of the first transistor T1, thereby initializing a gate voltage of the first transistor T1.

The fifth transistor T5 may include a gate electrode G5 connected to the emission control line EL, a first electrode E51 connected to the power voltage line PL, and a second electrode E52 connected to the first electrode E11 of the first transistor T1 and the second electrode E22 of the second transistor T2.

The sixth transistor T6 may include a gate electrode G6 connected to the emission control line EL, a first electrode E61 connected to the second electrode E12 of the first transistor T1 and the first electrode E31 of the third transistor T3, and a second electrode E62 connected to the pixel electrode of the organic light-emitting diode OLED.

The fifth transistor T5 and the sixth transistor T6 may be simultaneously turned on in response to the emission control signal EM received via the emission control line EL, so that current may flow in the organic light-emitting diode OLED.

The seventh transistor T7 may include a gate electrode G7 connected to the second scan line SL2, a first electrode E71 connected to the second electrode E62 of the sixth transistor T6 and the pixel electrode of the organic light-emitting diode OLED, and a second electrode E72 connected to the initialization voltage line VIL. The seventh transistor T7 may be turned on in response to the second scan signal GI received via the second scan line SL2 and may initialize a voltage of the pixel electrode of the organic light-emitting diode OLED. The seventh transistor T7 may be omitted.

In FIG. 4B, the fourth transistor T4 and the seventh transistor T7 are connected to the second scan line SL2. However, one or more embodiments are not limited thereto. In another embodiment, the fourth transistor T4 may be connected to the second scan line SL2, and the seventh transistor T7 may be connected to a separate line so as to be driven according to a signal received via the line.

The capacitor Cst may include the lower electrode CE1 connected to the gate electrode G1 of the first transistor T1, and the upper electrode CE2 connected to the power voltage line PL. The lower electrode CE1 of the capacitor Cst may also be connected to the second electrode E32 of the third transistor T3 and the second electrode E42 of the fourth transistor T4.

The organic light-emitting diode OLED may include a pixel electrode, an opposite electrode, and an emission layer between the pixel electrode and the opposite electrode, and the opposite electrode may receive the second power voltage ELVSS. The organic light-emitting diode OLED may receive the driving current I_{oled} from the first transistor T1, emit light, and display an image.

Although a case in which a display element includes an organic light-emitting diode is described herein, one or more embodiments are not limited thereto. For example, the display element may include an inorganic light-emitting diode or the like.

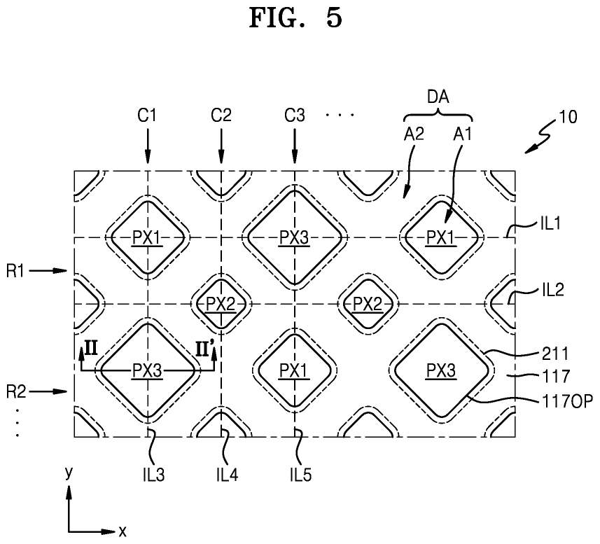

FIG. 5 is a partial schematic plan view illustrating a pixel array in a display panel 10 according to an embodiment. FIG. 6 is a schematic cross-sectional view taken along line II-II′ in FIG. 5.

Pixels arranged in the display area DA of the display panel 10 may include a first pixel PX1, a second pixel PX2, and a third pixel PX3. The first pixel PX1, the second pixel PX2, and the third pixel PX3 may be repeatedly arranged according to a pattern in column and row directions. Each of the first pixel PX1, the second pixel PX2, and the third pixel PX3 may include a pixel circuit and an organic light-emitting diode OLED electrically connected to the pixel circuit. The organic light-emitting diode OLED of each of the pixels may be disposed directly on the pixel circuit to overlap the pixel circuit, and may be offset from the pixel circuit to overlap a pixel circuit of a pixel in an adjacent row or column. A pixel array may be an array of the organic light-emitting diode OLED of each of the first pixel PX1, the second pixel PX2, and the third pixel PX3, or an array of a pixel electrode 211 included in the organic light-emitting diode OLED.

In each row R1, R2, . . . , the pixel electrode 211 of the first pixel PX1, the pixel electrode 211 of the second pixel PX2, the pixel electrode 211 of the third pixel PX3, and the pixel electrode 211 of the second pixel PX2 may be apart from each other and alternately arranged with each other in a zigzag shape. The pixel electrode 211 of the first pixel PX1 and the pixel electrode 211 of the third pixel PX3 may be apart from each other and alternately arranged with each other on a first imaginary straight line IL1 in a first direction (x direction). The pixel electrode 211 of the second pixel PX2 may be offset from the pixel electrode 211 of the first pixel PX1 and the pixel electrode 211 of the third pixel PX3 in the first direction (x direction) and a second direction (y direction) and repeatedly arranged on a second imaginary straight line IL2 in the first direction (x direction).

In a first column C1, the pixel electrode 211 of the first pixel PX1 and the pixel electrode 211 of the third pixel PX3 may be apart from each other and alternately arranged with each other on a third imaginary straight line IL3 in the second direction (y direction). In a second column C2, which is adjacent to the first column C1, the pixel electrode 211 of the second pixel PX2 may be apart from each other and repeatedly arranged on a fourth imaginary straight line IL4 in the second direction (y direction). In a third column C3, which is adjacent to the second column C2, in contrast to the first column C1, the pixel electrode 211 of the third pixel PX3 and the pixel electrode 211 of the first pixel PX1 may be apart from each other and alternately arranged with each other on a fifth imaginary straight line IL5 in the second direction (y direction).

The pixel electrode 211 of the first pixel PX1, the pixel electrode 211 of the second pixel PX2, and the pixel electrode 211 of the third pixel PX3 may differ in area from each other. In an embodiment, the pixel electrode 211 of the third pixel PX3 may have an area greater than an area of the pixel electrode 211 of the first pixel PX1 adjacent thereto. The pixel electrode 211 of the third pixel PX3 may have an area greater than an area of the pixel electrode 211 of the second pixel PX2 adjacent thereto. The pixel electrode 211 of the second pixel PX2 may have an area smaller than an area of the pixel electrode 211 of the first pixel PX1 adjacent thereto. In another embodiment, the pixel electrode 211 of the third pixel PX3 may have an area equal to an area of the pixel electrode 211 of the first pixel PX1. The pixel electrode 211 may have a polygonal shape, such as a quadrangle and an octagon, a circular shape, and an elliptical shape, and the polygonal shape may include a shape with round vertices.

The first to third pixels PX1, PX2, and PX3 may emit light of different colors. In an embodiment, the first pixel PX1 may be a red pixel emitting red light, the second pixel PX2 may be a green pixel emitting green light, and the third pixel PX3 may be a blue pixel emitting blue light. In another embodiment, the first pixel PX1 may be a red pixel, the second pixel PX2 may be a blue pixel, and the third pixel PX3 may be a green pixel. A combination of colors of light emitted from the first to third pixels PX1, PX2, and PX3 may be variously changed.

In FIG. 5, an arrangement of the first pixel PX1, the second pixel PX2, and the third pixel PX3 has a PenTile™ structure. However, one or more embodiments are not limited thereto. For example, the pixels may be arranged in a stripe structure. In other words, the first pixel PX1, the second pixel PX2, and the third pixel PX3 may be sequentially arranged in the x direction. In another embodiment, the first pixel PX1, the second pixel PX2, and the third pixel PX3 may be arranged in various pixel array structures, such as a mosaic structure and a delta structure.

The display area DA of the substrate 100 may include a first area A1 and a second area A2 around the first area A1. The first area A1 may be an area in which the organic light-emitting diodes OLED of the respective first, second, and third pixels PX1, PX2, and PX3 are disposed. The pixel electrode 211 may be arranged in the first area A1, and an area of the first area A1 may be less than an area of the pixel electrode 211. The second area A2 may be an area surrounding the first area A1 and an area located between multiple first areas A1. A third insulating layer 117 may be arranged in the second area A2. The first area A1 may correspond to an exposure area of the pixel electrode 211 by an opening 117OP of the third insulating layer 117, and the second area A2 may correspond to an area in which the third insulating layer 117 between the pixel electrodes 211 is arranged. Accordingly, the first area A1 and the second area A2 of the substrate 100 may be understood as a first area A1 and a second area A2 of the pixel PX, respectively. Herein, the first area A1 is defined as an area corresponding to a bottom surface of the opening 117OP of the third insulating layer 117 having a minimum area, when the opening 117OP of the third insulating layer 117 is viewed from above. In FIG. 5, an outline of the bottom surface of the opening 117OP of the third insulating layer 117 is indicated by a solid line, and an outline of the pixel electrode 211 is indicated by dotted lines.

Referring to FIG. 6, a buffer layer 111 may be disposed on the substrate 100 to prevent impurities from permeating into a semiconductor layer of a thin-film transistor.

The substrate 100 may include various materials, including a glass material, a metal material, and/or a plastic material. According to an embodiment, the substrate 100 may be a flexible substrate and may include a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), and/or cellulose acetate propionate (CAP). The buffer layer 111 may include an inorganic insulating material, such as silicon nitride and/or silicon oxide, and may be a single layer or multiple layers.

On the substrate 100, a thin-film transistor TFT, a capacitor Cst, and an organic light-emitting diode 200 electrically connected to the thin-film transistor TFT may be disposed. In case that the organic light-emitting diode 200 is electrically connected to the thin-film transistor TFT, it may be understood that the pixel electrode 211 is electrically connected to the thin-film transistor TFT. The thin-film transistor TFT may be the first transistor T1 in FIGS. 4A and 4B.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, and/or an organic semiconductor material. The gate electrode 134 may include a single layer or multiple layers of one or more materials from among aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), considering adhesion to an adjacent layer, a surface flatness and processability of a layer to be stacked thereon, and the like.

A gate insulating layer 112 including an inorganic material, such as silicon oxide, silicon nitride, and/or silicon oxynitride, may be located between the semiconductor layer 132 and the gate electrode 134. A first interlayer insulating layer 113 and a second interlayer insulating layer 114 each including an inorganic material, such as silicon oxide, silicon nitride, and/or silicon oxynitride, may be arranged between the gate electrode 134 and the source electrode 136S and between the gate electrode 134 and the drain electrode 136D. The source electrode 136S and the drain electrode 136D may be electrically connected to the semiconductor layer 132 via contact holes defined in the gate insulating layer 112, the first interlayer insulating layer 113, and the second interlayer insulating layer 114.

Each of the source electrode 136S and the drain electrode 136D may include a single layer or multiple layers of one or more materials from among Al, Pt, Pd, Ag, Mg, Au, Ni, Nd, Ir, Cr, Li, Ca, Mo, Ti, W, and Cu.

The capacitor Cst may include the lower electrode CE1 and the upper electrode CE2 overlapping each other with the interlayer insulating layer 113 therebetween. The capacitor Cst may overlap the thin-film transistor TFT. FIG. 6 shows that the gate electrode 134 of the thin-film transistor TFT is the lower electrode CE1 of the capacitor Cst. In another embodiment, the capacitor Cst may not overlap the thin-film transistor TFT. The capacitor Cst may be covered by the second interlayer insulating layer 114.

A pixel circuit including the thin-film transistor TFT and the capacitor Cst may be covered by a first insulating layer 115 and a second insulating layer 116. The first insulating layer 115 and the second insulating layer 116 may be planarized insulating layers and organic insulating layers. Each of the first insulating layer 115 and the second insulating layer 116 may include an organic insulating material, such as general-purpose polymers, such as poly (methyl methacrylate) (PMMA) or polystyrene (PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, and a blend thereof. In an embodiment, the first insulating layer and the second insulating layer 116 may each include PI.

A display element, for example, the organic light-emitting diode 200, may be disposed on the second insulating layer 116. The organic light-emitting diode 200 may include the pixel electrode 211, an intermediate layer 231, and an opposite electrode 251.

The pixel electrode 211 may be disposed on the second insulating layer 116 and connected to the thin-film transistor via a connection electrode 181 on the first insulating layer 115. A line 183, such as a data line DL and a power line PL, may be disposed on the first insulating layer 115.

The pixel electrode 211 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the pixel electrode 211 may include a reflective film including Ag, Mg, Al, Pt, Pd, Au, Ni, Nd, Ir, Cr, and/or a compound thereof. In another embodiment, the pixel electrode 211 may further include a film including ITO, IZO, ZnO, or In₂O₃, on/under the reflective film described above.

The third insulating layer 117 may be disposed on the second insulating layer 116. The third insulating layer 117 may cover an edge of the pixel electrode 211 and may be a pixel-defining layer that defines a pixel by the opening 117OP of the third insulating layer 117, through which a portion of the pixel electrode 211 is exposed. The opening 117OP of the third insulating layer 117 may correspond to the first area A1. The third insulating layer 117 may increase a distance between an edge of the pixel electrode 211 and the opposite electrode 251, thereby preventing an arc or the like from occurring at the edge of the pixel electrode 211. The third insulating layer may include an organic material, such as PI or hexamethyldisiloxane (HMDSO).

The intermediate layer 231 may include an emission layer. The emission layer may include a polymer or low-molecular weight organic material that emits light of a color. In an embodiment, the intermediate layer 231 may include a first functional layer disposed under the emission layer, and/or a second functional layer disposed on the emission layer. The first functional layer and/or the second functional layer may include a layer integrally provided as a single body across multiple pixel electrodes 211, and may include a layer patterned to correspond to each of the pixel electrodes 211.

The first functional layer may be a single layer or multiple layers. For example, in case that the first functional layer includes a polymer material, the first functional layer may include a hole transport layer (HTL) as a single layer, and may include poly(3,4-ethylenedioxythiophene) (PEDOT) or polyaniline (PANI). In case that the first functional layer includes a low-molecular weight material, the first functional layer may include a hole injection layer (HIL) and the HTL.

The second functional layer is not necessarily provided all the time. For example, in case that the first functional layer and the emission layer each include a polymer material, the second functional layer may be formed so that characteristics of the organic light-emitting diode become excellent. The second functional layer may be a single layer or multiple layers. The second functional layer may include an electron transport layer (ETL) and/or an electron injection layer (EIL).

The opposite electrode 251 may be arranged to face the pixel electrode 211 with the intermediate layer 231 therebetween. The opposite electrode 251 may include a conductive material having a low work function. For example, the opposite electrode 251 may include a (semi-)transparent layer including Ag, Mg, Al, Pt, Pd, Au, Ni, Nd, Ir, Cr, Li, Ca, and/or an alloy thereof. In other embodiments, the opposite electrode 251 may further include a layer, including ITO, IZO, ZnO, and/or In₂O₃, on the (semi-)transparent layer including the materials described above.

The opposite electrode 251 may be disposed on the intermediate layer 231 and the third insulating layer 117. The opposite electrode 251 may be integrally provided as a single body in the organic light-emitting diodes 200 in the display area DA, and may face the pixel electrodes 211.

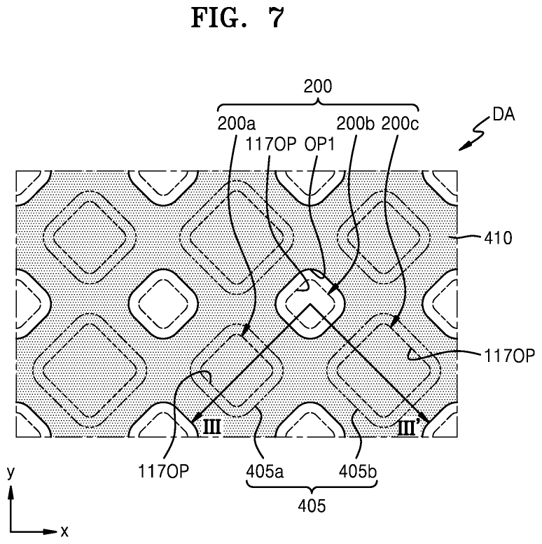

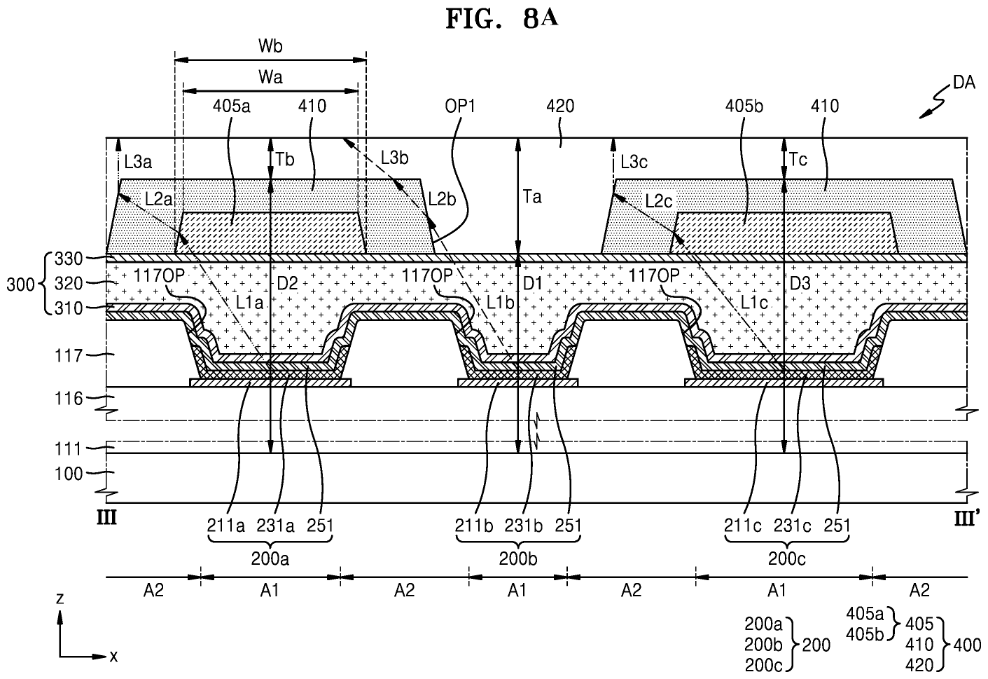

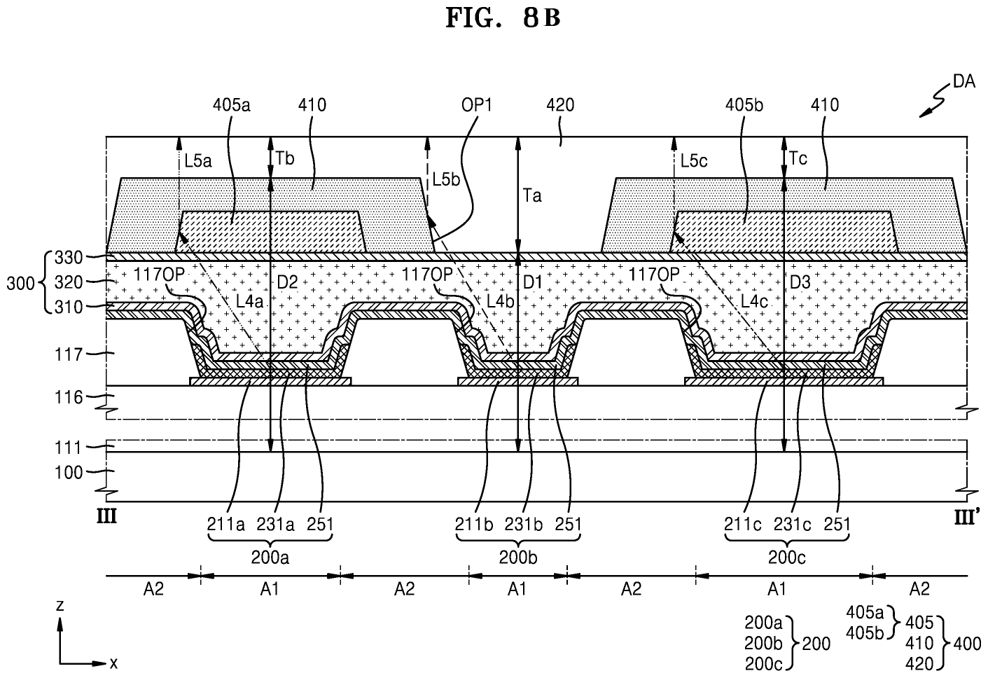

FIG. 7 is a partial schematic plan view illustrating a portion of a refractive layer according to an embodiment. FIGS. 8A and 8B are schematic cross-sectional views taken along line III-III′ in FIG. 7. FIGS. 8A and 8B each show an optical path according to a relative refractive index of the refractive layer. Descriptions provided above with reference to FIGS. 5 and 6 are omitted below.

Referring to FIGS. 7, 8A, and 8B, the organic light-emitting diode 200 may include a first organic light-emitting diode 200a, a second organic light-emitting diode 200b, and a third organic light-emitting diode 200c, which respectively correspond to the first pixel PX1, the second pixel PX2, and the third pixel PX3 described with reference to FIG. 5. In the display area DA, the first area A1 may be an area in which the first organic light-emitting diode 200a of the first pixel PX1, the second organic light-emitting diode 200b of the second pixel PX2, and the third organic light-emitting diode 200c of the third pixel PX3 are located. The first organic light-emitting diode 200a may include a first pixel electrode 211a, a first intermediate layer 231a, and the opposite electrode 251. The second organic light-emitting diode 200b may include a second pixel electrode 211b, a second intermediate layer 231b and the opposite electrode 251. The third organic light-emitting diode 200c may include a third pixel electrode 211c, a third intermediate layer 231c, and the opposite electrode 251.

A thin-film encapsulation layer may be disposed on the first to third organic light-emitting diodes 200a, 200b, and 200c as the encapsulation member 300. The thin-film encapsulation layer may be disposed on the opposite electrode 251. The thin-film encapsulation layer may protect the organic light-emitting diodes 200 from moisture, oxygen, or the like from the outside. The thin-film encapsulation layer may have a multi-layer structure. The thin-film encapsulation layer may include a first inorganic layer 310, an organic layer 320, and a second inorganic layer 330. In case that the thin-film encapsulation layer includes a multi-layer structure, even in case that cracks occur in the thin-film encapsulation layer, the cracks may be prevented from being connected between the first inorganic layer 310 and the organic layer 320 or between the organic layer 320 and the second inorganic layer 330. Through this, the formation of a passage through which moisture, oxygen, or the like from the outside permeates may be prevented or minimized. In another embodiment, the number of organic layers, the number of inorganic layers, and a stack order may be changed.

The first inorganic layer 310 may cover the opposite electrode 251, and may include one or more inorganic insulating materials, such as aluminum oxide, titanium oxide, tantalum oxide, hafnium oxide, zinc oxide, silicon oxide, silicon nitride, and/or silicon oxynitride. Because the first inorganic layer 310 is formed along a structure thereunder, an upper surface of the first inorganic layer 310 may not be flat.

The organic layer 320 may cover the first inorganic layer 310 and may have a sufficient thickness. An upper surface of the organic layer 320 may be substantially flat throughout the display area DA. The organic layer 320 may include PET, PEN, PC, PI, polyethylene sulfonate, polyoxymethylene, polyarylate, HMDSO, acryl-based resin (e.g., PMMA, polyacrylic acid, etc.), or any combination thereof.

The second inorganic layer 330 may cover the organic layer 320, and may include one or more inorganic insulating materials from among aluminum oxide, titanium oxide, tantalum oxide, hafnium oxide, zinc oxide, silicon oxide, silicon nitride, and silicon oxynitride. The second inorganic layer 330 may extend to the outside of the organic layer 320 and may be in contact with the first inorganic layer 310 in the peripheral area PA (see FIGS. 1 and 2), so that the organic layer 320 may not be exposed to the outside.

Accordingly, in a process of forming the thin-film encapsulation layer, in order to prevent damage to a structure thereunder, at least one capping layer and/or a protective layer may be located between the opposite electrode 251 and the thin-film encapsulation layer. The protective layer may include an inorganic material.

The refractive layer 400 may be disposed over the organic light-emitting diode 200. For example, the refractive layer may be disposed over the encapsulation member 300. The refractive layer 400 may adjust a path of light emitted from the emission layer of the organic light-emitting diode 200.

The refractive layer 400 may include a first refractive layer 410 and a second refractive layer 420 having different refractive indices from each other. A difference in refractive index between the first refractive layer 410 and the second refractive layer 420 may be, for example, in a range of about 0.1 to about 0.5. In an embodiment, the refractive layer 400 may further include a lower refractive pattern 405 between the first refractive layer 410 and the encapsulation member 300. Each of the first refractive layer 410, the second refractive layer 420, and the lower refractive pattern 405 may be formed by, for example, a photo process or an inkjet printing process. For example, the lower refractive pattern 405 and the first refractive layer 410 may be formed by the photo process, and the second refractive layer 420 may be formed by the inkjet printing process.

The first refractive layer 410 may be disposed on the encapsulation member 300. For example, the first refractive layer 410 may be disposed on the second inorganic layer 330. In an embodiment, the first refractive layer 410 may include a first opening OP1 exposing an uppermost surface of the encapsulation member 300 in an area of the first refractive layer 410 overlapping the second organic light-emitting diode 200b. In FIG. 7, a bottom surface of the first opening OP1 of the first refractive layer 410 is indicated by a solid line, and an outline of a bottom surface of the opening 117OP of the third insulating layer 117 is indicated by dotted lines. The first opening OP1 of the first refractive layer 410 may surround the opening 117OP of the third insulating layer 117 and overlap the opening 117OP of the third insulating layer 117. In an embodiment, a size of the first opening OP1 of the first refractive layer 410 may be greater than a size of the opening 117OP of the third insulating layer 117. A shape of the first opening OP1 of the first refractive layer 410 may correspond to a shape of the opening 117OP of the third insulating layer 117. In FIG. 7, the shape of the first opening OP1 is a quadrangle. However, in another embodiment, the shape of the first opening OP1 may be a polygon, such as a circle, an ellipse, and a triangle. The polygon may include a shape with round edges.

In an embodiment, the first refractive layer 410 may not overlap the second organic light-emitting diode 200b. In an embodiment, the first refractive layer 410 may overlap the first and third organic light-emitting diodes 200a and 200c.

The second refractive layer 420 may be disposed on the first refractive layer 410 and may fill the first opening OP1 of the first refractive layer 410. The second refractive layer 420 may be in contact with an upper surface of the encapsulation member 300 exposed through the first opening OP1, for example, the second inorganic layer 330. The second refractive layer 420 may cover an entire surface of an upper portion of the substrate 100, and the upper surface may be approximately flat.

A thickness Ta of the second refractive layer 420 in an area overlapping with the second organic light-emitting diode 200b may be greater than a thickness Tb of the second refractive layer 420 in an area overlapping the first organic light-emitting diode 200a. For example, the thickness Ta of the second refractive layer 420 in an area overlapping a central portion of the second organic light-emitting diode 200b may be greater than the thickness Tb of the second refractive layer 420 in an area overlapping a central portion of the first organic light-emitting diode 200a. The thickness Ta of the second refractive layer 420 in the area overlapping the second organic light-emitting diode 200b may be greater than a thickness Tc of the second refractive layer 420 in an area overlapping the third organic light-emitting diode 200c. For example, the thickness Ta of the second refractive layer 420 in the area overlapping the central portion of the second organic light-emitting diode 200b may be greater than the thickness Tc of the second refractive layer 420 in an area overlapping a central portion of the third organic light-emitting diode 200c. A thickness of the second refractive layer 420 described above may be defined as an average thickness thereof in one area.

In an embodiment, a distance D1 between the upper surface of the substrate 100 and a lower surface of the second refractive layer 420 in the area overlapping the second organic light-emitting diode may be less than a distance D2 between the upper surface of the substrate 100 and the lower surface of the second refractive layer 420 in the area overlapping the first organic light-emitting diode 200a. For example, the distance D1 between the upper surface of the substrate 100 and the lower surface of the second refractive layer 420 in the area overlapping the central portion of the second organic light-emitting diode 200b may be less than the distance D2 between the upper surface of the substrate 100 and the lower surface of the second refractive layer in the area overlapping the central portion of the first organic light-emitting diode 200a. In an embodiment, the distance D1 between the upper surface of the substrate 100 and the lower surface of the second refractive layer 420 in the area overlapping the second organic light-emitting diode 200b may be less than a distance D3 between the upper surface of the substrate 100 and the lower surface of the second refractive layer 420 in the area overlapping the third organic light-emitting diode 200c. For example, the distance D1 between the upper surface of the substrate 100 and the lower surface of the second refractive layer 420 in the area overlapping the central portion of the second organic light-emitting diode 200b may be less than the distance D3 between the upper surface of the substrate 100 and the lower surface of the second refractive layer 420 in the area overlapping the central portion of the third organic light-emitting diode 200c.

The lower surface of the second refractive layer 420 in the area overlapping the second organic light-emitting diode 200b may be located to be closer to the encapsulation member 300 than the lower surface of the second refractive layer 420 in the area overlapping the first organic light-emitting diode 200a. The lower surface of the second refractive layer 420 in the area overlapping the second organic light-emitting diode 200b may be located to be closer to the encapsulation member 300 than the lower surface of the second refractive layer 420 in the area overlapping the third organic light-emitting diode 200c.

In an embodiment, in the area overlapping the second organic light-emitting diode 200b, the second refractive layer 420 may be in contact with the encapsulation member 300. In an embodiment, in the area overlapping the first organic light-emitting diode 200a, the second refractive layer 420 may be in contact with the first refractive layer 410. In an embodiment, in the area overlapping the third organic light-emitting diode 200c, the second refractive layer 420 may be in contact with the first refractive layer 410.

A portion of the second refractive layer 420 in the area overlapping the second organic light-emitting diode 200b may be surrounded by the first refractive layer 410. A portion of the second refractive layer 420 located in the first opening OP1 of the first refractive layer 410 may be surrounded by the first refractive layer 410.

The lower refractive pattern 405 may include a first lower refractive pattern 405a and a second lower refractive pattern 405b. Each of the first lower refractive pattern 405a and the second lower refractive pattern 405b may be, for example, a pattern having an island or isolated shape. In an embodiment, the lower refractive pattern 405 may have an inclined sidewall. In an embodiment, a width Wa of an upper surface of the lower refractive pattern 405 may be less than a width Wb of a lower surface of the lower refractive pattern 405. A width of an upper surface of the first lower refractive pattern 405a may be less than a width of a lower surface of the first lower refractive pattern 405a. A width of an upper surface of the second lower refractive pattern 405b may be less than a width of a lower surface of the second lower refractive pattern 405b.

The first lower refractive pattern 405a may be arranged between the first refractive layer 410 and the encapsulation member 300 in the area overlapping the first organic light-emitting diode 200a. The second lower refractive pattern 405b may be arranged between the first refractive layer 410 and the encapsulation member 300 in the area overlapping the third organic light-emitting diode 200c. Each of the first lower refractive pattern 405a and the second lower refractive pattern 405b may have a refractive index different from a refractive index of the first refractive layer 410. For example, a difference in refractive index between the first refractive layer 410 and the first lower refractive pattern 405a may be in a range of about 0.1 to about 0.5. For example, a difference in refractive index between the first refractive layer 410 and the second lower refractive pattern 405b may be in a range of about 0.1 to about 0.5. In an embodiment, the first lower refractive pattern 405a and the second lower refractive pattern 405b may include the same material. In an embodiment, each of the first lower refractive pattern 405a and the second lower refractive pattern 405b may have a refractive index substantially equal to a refractive index of the second refractive layer 420. However, one or more embodiments are not limited thereto.

In an embodiment, as shown in FIG. 7, the lower refractive pattern 405 may surround the opening 117OP of the third insulating layer 117. However, one or more embodiments are not limited thereto. The first lower refractive pattern 405a may surround the opening 117OP of the third insulating layer 117. The first lower refractive pattern 405a may overlap the first organic light-emitting diode 200a. The second lower refractive pattern 405b may surround the opening 117OP of the third insulating layer 117. The second lower refractive pattern 405b may overlap the third organic light-emitting diode 200c. A size of the first lower refractive pattern 405a may be greater than a size of the opening 117OP of the third insulating layer 117. However, one or more embodiments are not limited thereto. In another embodiment, the size of the first lower refractive pattern 405a may be less than the size of the opening 117OP of the third insulating layer 117. A size of the second lower refractive pattern 405b may be greater than the size of the opening 117OP of the third insulating layer 117. However, one or more embodiments are not limited thereto. In another embodiment, the size of the second lower refractive pattern 405b may be less than the size of the opening 117OP of the third insulating layer 117. In FIG. 7, the shape of the lower refractive pattern 405 is a quadrangle. However, in another embodiment, the shape of the lower refractive pattern 405 may be a circle, an ellipse, or a polygon, such as a triangle. The polygon may include a shape with round edges.

Each of the first refractive layer 410, the second refractive layer 420, and the lower refractive pattern 405 may include a first material having a first refractive index, and a second material having a second refractive index that is less than the first refractive index.

The first material may include a light-transmitting inorganic material or organic material having a high refractive index. For example, the inorganic material of the first material may include zinc oxide, titanium oxide, zirconium oxide, niobium oxide, tantalum oxide, tin oxide, nickel oxide, silicon nitride, indium nitride, gallium nitride, etc. For example, the organic material of the first material may include at least one selected from the group consisting of PEDOT, 4,4′-Bis[N-(3-methylphenyl)-N-phenylamino]biphenyl (TPD), 4,4′4″-Tris(N-3-methylphenyl-N-phenylamino)-triphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5,-tris[N,N-bis(4-methylphenyl)-amino]-benzene (p-MTDAB), 4,4′-bis[N,N-bis(3-methylphenyl)-amino]-diphenylmethane (BPPM), 4,4′-dicarbazolyl-1,1′-biphenyl (CBP), 4,4′,4″-tris(N-carbazole)triphenylamine (TCTA), 2,2′,2″-(1,3,5-benzene tolyl) tris-[1-phenyl-1H-benzoimidazole] (TPBI), and 3-(4-biphenyl)-4-phenyl-5-t-butylphenyl-1,2,4-triazole (TAZ).

The second material may include a light-transmitting inorganic material or organic material having a low refractive index. For example, the inorganic material of the second material may include silicon oxide, magnesium fluoride, etc. For example, the organic material of the second material may include at least one selected from the group consisting of acrylic, PI, polyamide, and Alq3[Tris(8-hydroxyquinolinato)aluminium].

The first refractive index of the first material may be in a range of, for example, about 1.6 to about 1.7. The second refractive index of the second material may be in a range of, for example, about 1.2 to about 1.5.

FIG. 8A illustrates an embodiment in which each of the second refractive layer 420 and the lower refractive pattern 405 has a refractive index lower than a refractive index of the first refractive layer 410. In an embodiment, the second refractive layer 420 may have a refractive index lower than the refractive index of the first refractive layer 410. Each of the first lower refractive pattern 405a and the second lower refractive pattern 405b may have a refractive index lower than the refractive index of the first refractive layer 410. In an embodiment, the first refractive layer 410 may include the first material having the high refractive index described above, the second refractive layer 420 may include the second material having the low refractive index, and the lower refractive pattern 405 may include the second material having the low refractive index. In an embodiment, the first refractive layer 410 may have a refractive index in a range of about 1.6 to about 1.7, the second refractive layer 420 may have a refractive index in a range of about 1.2 to about 1.5, each of the first lower refractive pattern 405a and the second lower refractive pattern 405b may have a refractive index in a range of about 1.2 to about 1.5.

As shown in FIG. 8A, light L1a incident on a sidewall of the first lower refractive pattern 405a from among light emitted from the first organic light-emitting diode 200a may be refracted in a side direction according to a difference in refractive index at an interface with the first refractive layer 410 that is a high-refractive layer, so that a path of the light L1a may be changed. Light L2a refracted at the interface between the first refractive layer 410 and the first lower refractive pattern 405a may be refracted in a front direction at an interface between the first refractive layer 410 and the second refractive layer 420, so that a path of the light L2a may be changed. Light L3a refracted at the interface between the first refractive layer 410 and the second refractive layer 420 may be extracted in approximately a third direction (z direction). Accordingly, an area of an emission pattern of a pixel, the emission pattern in a front imaginary area may increase. In an embodiment, in case that the refractive layer 400 includes a structure in which a low-refractive pattern, a high-refractive layer, and a low-refractive layer are stacked on each other in order, in the area overlapping the first organic light-emitting diode 200a, light emitted from the first organic light-emitting diode 200a may be refracted in a side direction, thereby improving white angle difference (WAD) characteristics of the display apparatus.

As shown in FIG. 8A, light L1b incident on the second refractive layer 420 and facing in a direction toward the first refractive layer 410 from among light emitted from the second organic light-emitting diode 200b may be refracted in a side direction according to a difference in refractive index at an interface between a side surface of the first refractive layer 410, which is a high-refractive layer, and the second refractive layer 420. Light L2b refracted at the interface between the side surface of the first refractive layer 410 and the second refractive layer 420 may be refracted in a side direction at an interface between an upper surface of the first refractive layer 410 and the second refractive layer 420. Light L3b refracted at the interface between the upper surface of the first refractive layer 410 and the second refractive layer 420 may be diffused in the side direction. In an embodiment, in case that the refractive layer 400 includes a low-refractive layer surrounded by a high-refractive layer, in the area overlapping the second organic light-emitting diode 200b, light emitted from the second organic light-emitting diode 200b may be refracted in the side direction, thereby improving the WAD characteristics of the display apparatus.

As shown in FIG. 8A, light L1c incident on a sidewall of the second lower refractive pattern 405b from among light emitted from the third organic light-emitting diode 200c may be refracted in the side direction according to a difference in refractive index at an interface between the first refractive layer 410 and the second lower refractive pattern 405b. Light L2c refracted at the interface between the first refractive layer 410 and the second lower refractive pattern 405b may be refracted in the front direction at the interface between the first refractive layer 410 and the second refractive layer 420, and a path of the light L2c may be changed. Light L3c refracted at the interface between the first refractive layer 410 and the second refractive layer 420 may be extracted in approximately a third direction (z direction). Accordingly, an area of an emission pattern of a pixel generated in a front imaginary area may increase. In an embodiment, in case that the refractive layer 400 includes a structure in which a low-refractive pattern, a high-refractive layer, and a low-refractive layer are stacked on each other in order, in the area overlapping the third organic light-emitting diode 200c, light emitted from the third organic light-emitting diode 200c may be refracted in the side direction, thereby improving the WAD characteristics of the display apparatus.

FIG. 8B illustrates an embodiment in which each of the second refractive layer 420 and the lower refractive pattern 405 has a refractive index higher than a refractive index of the first refractive layer 410. In an embodiment, the second refractive layer 420 may have a higher refractive index than the first refractive layer 410. Each of the first lower refractive pattern 405a and the second lower refractive pattern 405b may have a higher refractive index than the first refractive layer 410. In an embodiment, the first refractive layer 410 may include the second material having the low refractive index described above, the second refractive layer 420 may include the first material having the high refractive index, and the lower refractive pattern 405 may include the first material having the high refractive index. In an embodiment, the first refractive layer 410 may have a refractive index in a range of about 1.2 to about 1.5, the second refractive layer 420 may have a refractive index in a range of about 1.6 to about 1.7, and each of the first lower refractive pattern 405a and the second lower refractive pattern 405b may have a refractive index in a range of about 1.6 to about 1.7.

As shown in FIG. 8B, light L4a incident on the sidewall of the first lower refractive pattern 405a from among light emitted from the organic light-emitting diode 200a may be refracted in the front direction according to a refractive index difference at an interface between the first refractive layer 410, which is a low refractive layer, and the first lower refractive pattern 405a. Light L5a refracted at the interface between the first refractive layer 410 and the first lower refractive pattern 405a may be extracted in approximately the third direction (z direction). Accordingly, frontal light extraction efficiency may be improved, and frontal visibility may be improved. In an embodiment, in case that the refractive layer 400 has a structure in which a high-refractive pattern, a low-refractive layer, and a high-refractive pattern are stacked on each other in order, in the area overlapping the first organic light-emitting diode 200a, light emitted from the first organic light-emitting diode 200a may be condensed in the front direction, thereby improving frontal visibility of the display apparatus.

As shown in FIG. 8B, light L4b incident on the second refractive layer 420 and facing in a direction toward the first refractive layer 410 from among light emitted from the second organic light-emitting diode 200b may be totally reflected at an interface with the side surface of the first refractive layer 410, which is a low-refractive layer, and a path of the light L4b may be changed. L5b, which is totally reflected, may be extracted in approximately the third direction (z direction). In case that the refractive layer 400 includes a high-refractive layer surrounded by a low-refractive layer, in an area overlapping the second organic light-emitting diode 200b, light emitted from the second organic light-emitting diode 200b may be condensed in the front direction, thereby improving the frontal visibility of the display apparatus.

As shown in FIG. 8B, light L4c incident on the sidewall of the second lower refractive pattern 405b from among light emitted from the third organic light-emitting diode 200c may be refracted in the front direction according to a refractive index difference at an interface with the first refractive layer 410, which is a low-refractive layer, and a path of the light L4c may be changed. Light L5c refracted between the interface between the first refractive layer 410 and the second lower refractive pattern 405b may be extracted in approximately the third direction (z direction). Accordingly, frontal light extraction efficiency may be improved, and frontal visibility may be improved. In an embodiment, in case that the refractive layer 400 has a structure in which a high-refractive layer, a low-refractive layer, and a high-refractive layer are stacked on each other in order, in the area overlapping the third organic light-emitting diode 200c, the light emitted from the first organic light-emitting diode 200a may be condensed in the front direction, and the frontal visibility of the display apparatus may be improved.

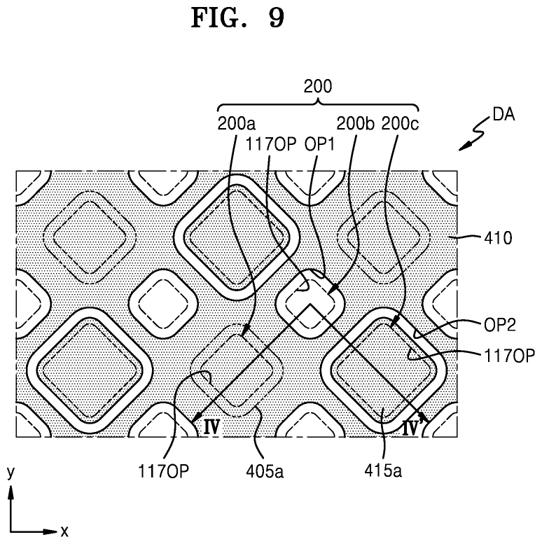

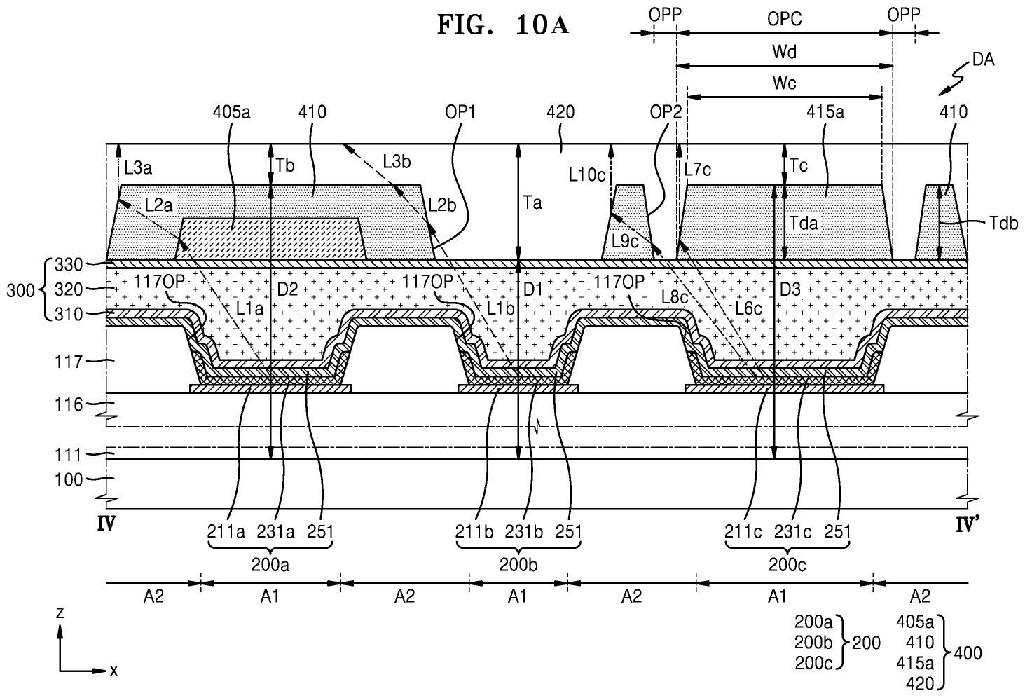

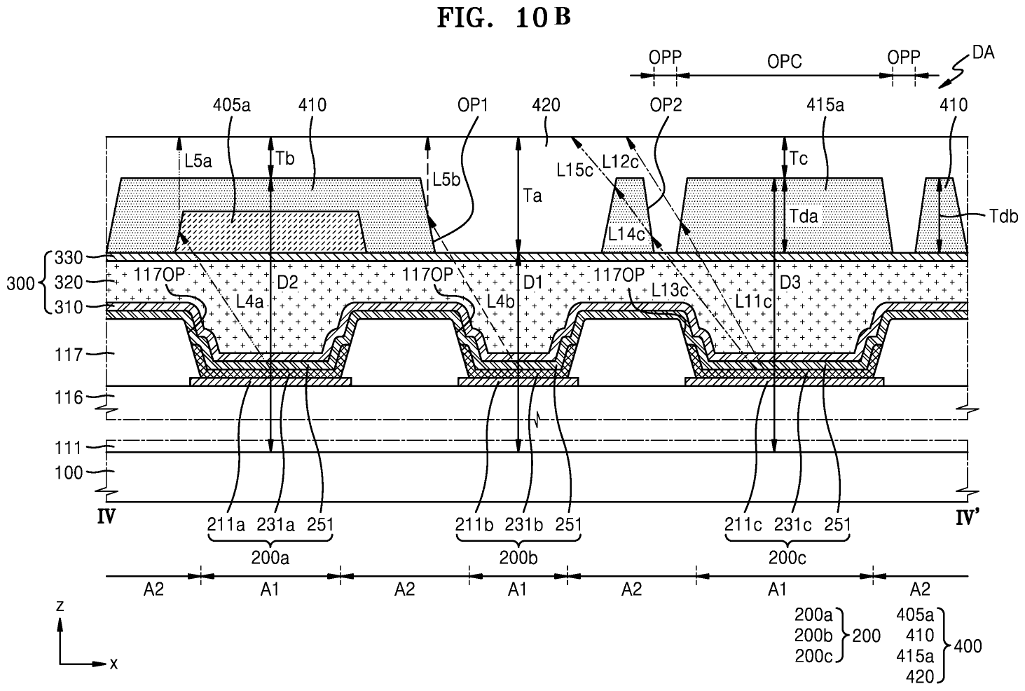

FIG. 9 is a partial schematic plan view illustrating a portion of a refractive layer according to an embodiment. FIGS. 10A and 10B are schematic cross-sectional views taken along line IV-IV′ in FIG. 9. Each of FIGS. 10A and 10B illustrates an optical path according to a relative refractive index of a refractive layer. Hereinafter, descriptions provided with reference to FIGS. 5 to 8B are omitted, and changes made to FIGS. 7 to 8B are described.

Referring to FIGS. 9, 10A, and 10B, the refractive layer 400 may include the first refractive layer 410, the second refractive layer 420, the first lower refractive pattern 405a, and the first refractive pattern 415a. Each of the first refractive layer 410, the second refractive layer 420, the first lower refractive pattern 405a, and the first refractive pattern 415a may be formed by a photo process or an inkjet printing process. For example, the first lower refractive pattern 405a, the first refractive pattern 415a, and the first refractive layer 410 may be formed by the photo process, and the second refractive layer 420 may be formed by the inkjet printing process.

In an embodiment, the first refractive layer 410 may include the first opening OP1 exposing an uppermost surface of the encapsulation member 300, in an area overlapping the second organic light-emitting diode 200b, and may include an opening OP2 exposing an uppermost surface of the encapsulation member 3000 in an area overlapping the third organic light-emitting diode 200c. In FIG. 9, bottom surfaces of the first opening OP1 and the second opening OP2 of the first refractive layer 410 are indicated by solid lines, and an outline of a bottom surface of the opening 117OP of the third insulating layer 117 is indicated by dotted lines. Each of the first opening OP1 and the second opening OP2 of the first refractive layer 410 may surround the opening 117OP of the third insulating layer 117 and overlap the opening 117OP of the third insulating layer 117. A size of each of the first opening OP1 and the second opening OP2 of the first refractive layer 410 may be greater than the size of the corresponding opening 117OP of the third insulating layer 117. A shape of each of the first opening OP1 and the second opening OP2 of the first refractive layer 410 may correspond to a shape of the opening 117OP of the third insulating layer 117. In FIG. 9, the shape of each of the first opening OP1 and the second opening OP2 is a quadrangle. However, in another embodiment, the shape of each of the first opening OP1 and the second opening OP2 may be a circle, an ellipse, or a polygon, such as a triangle. The polygon may include a shape with round edges.

In an embodiment, the first refractive layer 410 may not overlap the second organic light-emitting diode 200b and the third organic light-emitting diode 200c. In an embodiment, the first refractive layer 410 may overlap the first organic light-emitting diode 200a.

In an embodiment, the second refractive layer 420 may be disposed on the first refractive layer 410 and may fill the first opening OP1 and the second opening OP2 of the first refractive layer 410. In an embodiment, the second refractive layer 420 may be in contact with the encapsulation member 300 via the first opening OP1. In an embodiment, the second refractive layer 420 may be in contact with the upper surface of the encapsulation member 300 and the first refractive pattern 415a via the second opening OP2. The second refractive layer 420 may cover an entire surface of the upper portion of the substrate 100, and may have an approximately flat upper surface.

In an area overlapping the first organic light-emitting diode 200a, the first lower refractive pattern 405a may be arranged between the first refractive layer 410 and the encapsulation member 300. The first lower refractive pattern 405a may have a refractive index different from a refractive index of the first refractive layer 410. For example, a difference in refractive index between the first refractive layer 410 and the first lower refractive pattern 405a may be in a range of about 0.1 to about 0.5.

In an area overlapping the third organic light-emitting diode 200c, the first refractive pattern 415a may be arranged in the second opening OP2 of the first refractive layer 410. In an embodiment, the first refractive pattern 415a may include the same material as the first refractive layer 410. In other words, the first refractive pattern 415a may have a refractive index different from a refractive index of the second refractive layer 420. The first refractive pattern 415a may have a refractive index different from a refractive index of the first lower refractive pattern 405a. In an embodiment, the first refractive pattern 415a and the first refractive layer 410 may be formed in a same process operation, but are not limited thereto.

A thickness Tda of the first refractive pattern 415a may be substantially equal to a thickness Tdb of the first refractive layer 410. In an embodiment, the thickness Tda of the first refractive pattern 415a may be a distance between the upper surface of the encapsulation member 300 and an upper surface of the first refractive pattern 415a. In an embodiment, the thickness Tdb of the first refractive layer 410 may be a distance between the upper surface of the encapsulation member 300 and the upper surface of the first refractive layer 410. The distance between the upper surface of the encapsulation member 300 and the upper surface of the first refractive pattern 415a may be substantially equal to the distance between the upper surface of the encapsulation member 300 and the upper surface of the first refractive layer 410. A height of the upper surface of the first refractive pattern 415a may be substantially equal to a height of the upper surface of the first refractive layer 410. The height of the upper surface of the first refractive pattern 415a may be greater than a height of the upper surface of the first lower refractive pattern 405a. In an embodiment, the first refractive pattern 415a may have an inclined sidewall. For example, a width Wc of the upper surface of the first refractive pattern 415a may be less than a width Wd of a lower surface of the first refractive pattern 415a.

As shown in FIG. 9, the first refractive layer 410 may surround the first refractive pattern 415a.

As shown in FIGS. 10A and 10B, the second opening OP2 may include a central area OPC and a peripheral area OPP outside the central area OPC. The central area OPC of the second opening OP2 may be defined as an area in which the first refractive pattern 415a is arranged. The peripheral area OPP of the second opening OP2 may be defined as an area in which the first refractive pattern 415a is not arranged. The second refractive layer 420 may be arranged to fill the peripheral area OPP of the second opening OP2. The second refractive layer 420 may be arranged to surround the peripheral area OPP of the second opening OP2, and may surround the first refractive pattern 415a in a plan view. The first refractive layer 410 may surround a portion of the second refractive layer 420 located in the peripheral area OPP of the second opening OP2.

In an embodiment, as shown in FIG. 9, the first refractive pattern 415a may surround the opening 117OP of the third insulating layer 117. However, one or more embodiments are not limited thereto. The first refractive pattern 415a may overlap the third organic light-emitting diode 200c. A size of the first refractive pattern 415a may be greater than a size of the opening 117OP of the third insulating layer 117, but is not limited thereto. In another embodiment, the size of the first refractive pattern 415a may be less than the size of the opening 117OP of the third insulating layer 117. In FIG. 9, a shape of the first refractive pattern 415a is a quadrangle. However, in another embodiment, the shape of the first refractive pattern 415a may be a circle, an ellipse, or a polygon, such as a triangle. The polygon may include a shape with round edges.

The thickness Ta of the second refractive layer 420 in an area overlapping the second organic light-emitting diode 200b may be greater than the thickness Tb of the second refractive layer 420 in an area overlapping the first organic light-emitting diode 200a. For example, the thickness Ta of the second refractive layer 420 in an area overlapping a central portion of the second organic light-emitting diode 200b may be greater than the thickness Tb of the second refractive layer 420 in an area overlapping a central portion of the first organic light-emitting diode 200a. In case that the first refractive pattern 415a is arranged in the second opening OP2 of the first refractive layer 410 in an area overlapping the third organic light-emitting diode 200c, the thickness Ta of the second refractive layer 420 in an area overlapping the second organic light-emitting diode 200b may be greater than the thickness Tc of the second refractive layer 420 in an area overlapping the third organic light-emitting diode 200c. For example, the thickness of the second refractive layer 420 in the area overlapping the central portion of the second organic light-emitting diode 200b may be greater than the thickness Tc of the second refractive layer 420 in an area overlapping the central portion of the third organic light-emitting diode 200c. The thickness of the second refractive layer 420 described above may be defined as an average thickness thereof in one area. In an embodiment, the thickness Tb of the second refractive layer 420 in the area overlapping the central portion of the first organic light-emitting diode 200a may be substantially equal to the thickness Tc of the second refractive layer 420 in the area overlapping the central portion of the third organic light-emitting diode 200c. However, one or more embodiments are not limited thereto. In an embodiment, a distance between the upper surface of the first refractive layer 410 and the upper surface of the second refractive layer 420 in the area overlapping the first organic light-emitting diode 200a may be substantially equal to a distance between the upper surface of the first refractive pattern 415a and the upper surface of the second refractive layer 420 in the area overlapping the third organic light-emitting diode 200c.

The lower surface of the second refractive layer 420 in the area overlapping the second organic light-emitting diode 200b may be located to be closer to the encapsulation member 300 than the lower surface of the second refractive layer 420 in the area overlapping the first organic light-emitting diode 200a. The lower surface of the second refractive layer 420 in the area overlapping the second organic light-emitting diode 200b may be located to be closer to the encapsulation member 300 than the lower surface of the second refractive layer 420 in the area overlapping the third organic light-emitting diode 200c. In an embodiment, the second refractive layer 420 may be in contact with the encapsulation member 300 in the area overlapping the second organic light-emitting diode 200b. In an embodiment, the second refractive layer 420 may be in contact with the first refractive layer 410 in the area overlapping the first organic light-emitting diode 200a. In an embodiment, at least a portion of the second refractive layer 420 may be in contact with the first refractive pattern 415a in the area overlapping the third organic light-emitting diode 200c.

Each of the first refractive layer 410, the second refractive layer 420, the first lower refractive pattern 405a, and the first refractive pattern 415a may include a first material having a first refractive index, and a second material having a second refractive index that is lower than the first refractive index. The first material may include a light-transmitting inorganic material or organic material having a high refractive index. The second material may include a light-transmitting inorganic material or organic material having a low refractive index.

FIG. 10A illustrates an embodiment in which the second refractive layers 420 and the first lower refractive patterns 405a have lower refractive indices than the first refractive layer 410 and the first refractive pattern 415, respectively. In an embodiment, each of the first refractive layer 410 and the first refractive pattern 415a may include the first material having the high refractive index described above, and each of the second refractive layer 420 and the first lower refractive pattern 405a may include the second material having the low refractive index. In an embodiment, each of the first refractive layer 410 and the first refractive pattern 415a may have a refractive index in a range of about 1.6 to about 1.7, and each of the second refractive layer 420 and the first lower refractive pattern 405a may have a refractive index in a range of about 1.2 to about 1.5.

In FIG. 10A, paths of light emitted from the first organic light-emitting diode 200a and the second organic light-emitting diode 200b may respectively be the same as those described with reference to FIG. 8A, and thus, redundant descriptions thereof are omitted, and a path of light emitted from the third organic light-emitting diode 200c is described below.

As shown in FIG. 10A, light L6c incident on a sidewall of the first refractive pattern 415a from among light emitted from the third organic light-emitting diode 200c may be refracted in the front direction according to a refractive index difference at an interface with the second refractive layer 420 that is a low-refractive layer, and a path of the light L6c may be changed. Light L7c refracted at an interface between the first refractive pattern 415a and the second refractive layer 420 may be extracted in approximately the third direction (z direction). Light L8c incident on the second refractive layer 420 surrounding the first refractive pattern 415a from among light emitted from the third organic light-emitting diode 200c may be refracted in a side direction at an interface with a side surface of the first refractive layer 410 that is a high-refractive layer, and a path of the light L8c may be changed. Light L9c refracted at an interface between one side surface of the first refractive layer 410 and the second refractive layer 420 may be refracted in the front direction at an interface between another side surface of the first refractive layer 410 and the second refractive layer 420, and a path of the light L9c may be changed. Light L10c refracted at an interface between another side surface of the first refractive layer 410 and the second refractive layer 420 may be extracted in approximately the third direction (z direction).

In the embodiment of FIG. 10A, in an area overlapping the third organic light-emitting diode 200c, the refractive layer 400 includes the first refractive pattern 415a surrounded by the second refractive layer 420 that is a low-refractive layer, so that light emitted from the third organic light-emitting diode 200c is condensed in the front direction, thereby improving frontal visibility of the display apparatus. The light may be diffused in a side direction through a portion of the first refractive layer 410 surrounding the first refractive pattern 415a, so as to compensate for a side luminance ratio. In an embodiment, the light emitted from the third organic light-emitting diode 200c is emitted in the front direction of a wider range, so that an area of an emission pattern of a pixel generated in a frontal imaginary area may be increased.

FIG. 10B illustrates an embodiment in which the second refractive layer 420 and the first lower refractive pattern 405a have higher refractive indices than the first refractive layer 410 and the first refractive pattern 415a, respectively. In an embodiment, each of the first refractive layer 410 and the first refractive pattern 415a may include the second material having the low-refractive index described above, and each of the second refractive layer 420 and the first lower refractive pattern 405a may include the first material having the high-refractive index. In an embodiment, each of the first refractive layer 410 and the first refractive pattern 415a may have a refractive index in a range of about 1.2 to about 1.5, and each of the second refractive layer 420 and the first lower refractive pattern 405a may have a refractive index in a range of about 1.6 to about 1.7.

In FIG. 10B, paths of light emitted from the first organic light-emitting diode 200a and the second organic light-emitting diode 200b may respectively be the same as those described with reference to FIG. 8B, and thus, redundant descriptions thereof are omitted, and a path of light emitted from the third organic light-emitting diode 200c is described below.

As shown in FIG. 10B, light L11c incident on the first refractive pattern 415a from among light emitted from the third organic light-emitting diode 200c may be refracted in a side direction according to a refractive index difference at an interface with the second refractive layer 420 that is a high-refractive layer, and a path of the light L11c may be changed. Light L12c refracted at an interface between the first refractive pattern 415a and the second refractive layer 420 may be diffused in a side direction. Light L13c incident on the second refractive layer 420 surrounding the first refractive pattern 415a from among light emitted from the third organic light-emitting diode 200c may be refracted at an interface with a side surface of the first refractive layer 410 that is a low-refractive layer. Light L14c refracted at an interface between one side surface of the first refractive layer 410 and the second refractive layer 420 may be refracted in a side direction another side surface of the first refractive layer 410 and the second refractive layer 420. Light L15c refracted at an interface between another side surface of the first refractive layer 410 and the second refractive layer 420 may be diffused in a side direction.

In the embodiment of FIG. 10B, the refractive layer 400 includes the first refractive pattern 415a surrounded by the second refractive layer 420 that is a high-refractive layer, in an area overlapping the third organic light-emitting diode 200c, so that light emitted from the third organic light-emitting diode 200c is diffused in a side direction, thereby improving WAD characteristics.

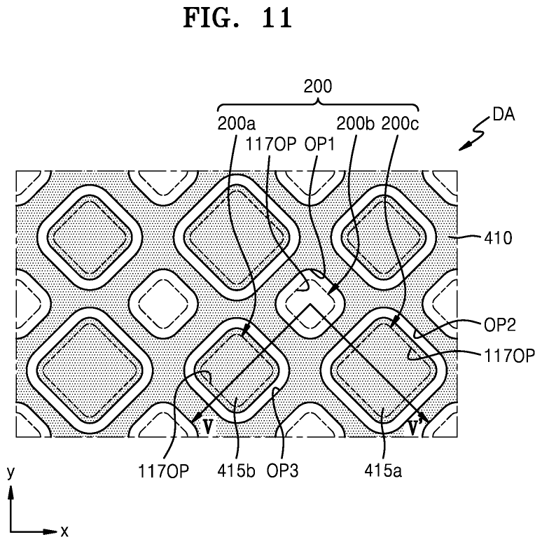

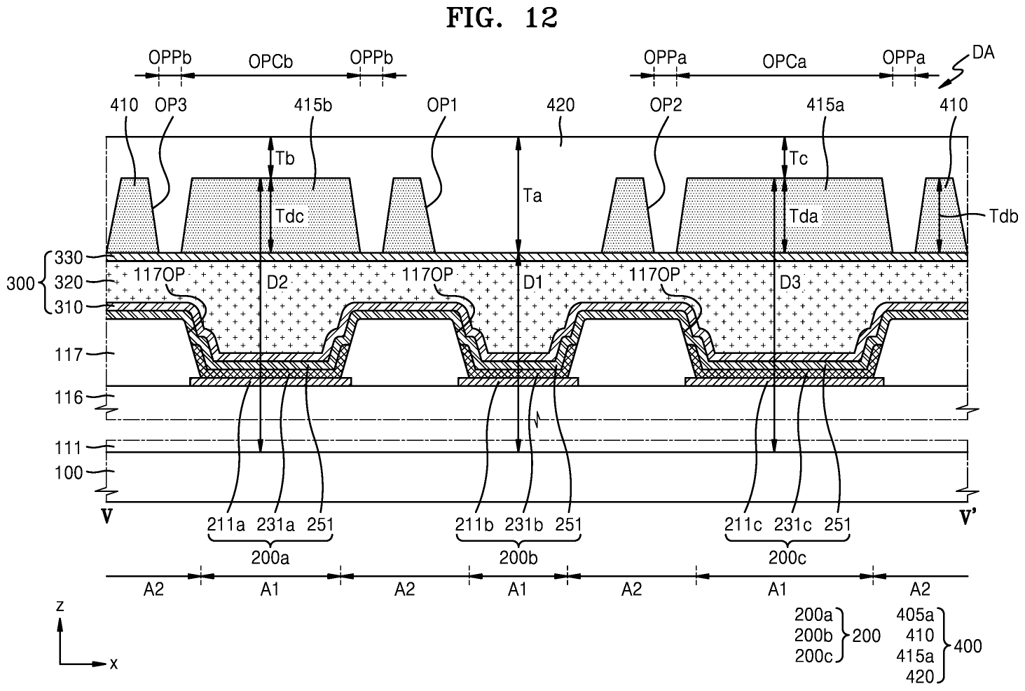

FIG. 11 is a partial schematic plan view illustrating a portion of the refractive layer 400 according to an embodiment. FIG. 12 is a schematic cross-sectional view taken along line V-V′ in FIG. 11. Hereinafter, the descriptions provided with reference to FIGS. 5 to 8B are omitted, and changes made to FIGS. 7 to 8B are described.

Referring to FIGS. 11 and 12, the refractive layer 400 may include the first refractive layer 410, the second refractive layer 420, the first refractive pattern 415a, and the second refractive pattern 415b. Each of the first refractive layer 410, the second refractive layer 420, the first refractive pattern 415a, and the second refractive pattern 415b may be formed by a photo process or an inkjet printing process. For example, the first refractive pattern 415a, the second refractive pattern 415b, and the first refractive layer 410 may be formed by a photo process, and the second refractive layer 420 may be formed by an inkjet printing process.

In an embodiment, the first refractive layer 410 may include the first opening OP1 that exposes an uppermost surface of the encapsulation member 300 in an area overlapping the second organic light-emitting diode 200b, and the second opening OP2 that exposes the uppermost surface of the encapsulation member 300 in an area overlapping the third organic light-emitting diode 200c. In an embodiment, the first refractive layer 410 may further include the third opening OP3 exposing the uppermost surface of the encapsulation member 300 in an area overlapping the first organic light-emitting diode 200a. In FIG. 11, bottom surfaces of the first opening OP1, the second opening OP2, and the third opening OP3 of the first refractive layer 410 are indicated by solid lines, and an outline of a bottom surface of the opening 117OP of the third insulating layer 117 is indicated by dotted lines. Each of the first to third openings OP1, OP2, and OP3 of the first refractive layer 410 may surround the opening 117OP of the third insulating layer 117 and overlap the opening 117OP of the third insulating layer 117. A size of each of the first to third openings OP1, OP2, and OP3 of the first refractive layer 410 may be greater than a size of the corresponding opening 117OP of the third insulating layer 117. The shape of each of the first to third openings OP1, OP2, and OP3 of the first refractive layer 410 may correspond to a shape of the opening 117OP of the third insulating layer 117. In FIG. 11, the shape of each of the first to third openings OP1, OP2, and OP3 is a quadrangle. However, in another embodiment, the shape of each of the first to third openings OP1, OP2, and OP3 may be a circle, an ellipse, or a polygon, such as a triangle. The polygon may include a shape with round edges.

In an embodiment, the first refractive layer 410 may not overlap the first organic light-emitting diode 200a, the second organic light-emitting diode 200b, and the third organic light-emitting diode 200c.

In an embodiment, the second refractive layer 420 may be disposed on the first refractive layer 410 to fill the first to third openings OP1, OP2, and OP3 of the first refractive layer 410. The second refractive layer 420 may cover an entire surface of an upper portion of the substrate 100, and may have an approximately flat upper surface.

In an area overlapping the third organic light-emitting diode 200c, the first refractive pattern 415a may be disposed in the second opening OP2 of the first refractive layer 410. In an embodiment, the first refractive pattern 415a and the first refractive layer 410 may include a same material. In other words, the first refractive pattern 415a and the second refractive layer 420 may have different refractive indices from each other. In an embodiment, the first refractive pattern 415a may be formed in a same process operation in which the first refractive layer 410 is formed. However, one or more embodiments are not limited thereto. The thickness Tda of the first refractive pattern 415a may be substantially equal to the thickness Tdb of the first refractive layer 410. A height of the upper surface of the first refractive pattern 415a may be substantially equal to a height of the upper surface of the first refractive layer 410. The thickness Tda of the first refractive pattern 415a may be a distance between the upper surface of the encapsulation of the encapsulation member 300 and the upper surface of the first refractive pattern 415a. The thickness Tdb of the first refractive layer 410 may be a distance between the upper surface of the encapsulation member 300 and the upper surface of the first refractive layer 410. The distance between the upper surface of the encapsulation member 300 and the upper surface of the first refractive pattern 415a may be substantially equal to the distance between the upper surface of the encapsulation member 300 and the upper surface of the first refractive layer 410.

In an area overlapping the first organic light-emitting diode, the second refractive pattern 415b may be arranged in the third opening OP3 of the first refractive layer 410. In an embodiment, the second refractive pattern 415b and the first refractive layer 410 may include a same material. In other words, the second refractive pattern 415b may have a refractive index different from a refractive index of the second refractive layer 420. In an embodiment, in case that the first refractive pattern 415a and the second refractive pattern 415b include a same material, the first refractive pattern 415a and the second refractive pattern 415b may have a same refractive index. In an embodiment, the second refractive pattern 415b may be formed in a same process operation in which the first refractive layer 410 is formed. However, one or more embodiments are not limited thereto. A thickness Tdc of the second refractive pattern 415b may be substantially equal to the thickness Tdb of the first refractive layer 410. A height of the upper surface of the second refractive pattern 415b may be substantially equal to a height of the upper surface of the first refractive layer 410. The thickness Tdc of the second refractive pattern 415b may be a distance between the upper surface of the encapsulation member 300 and the upper surface of the second refractive pattern 415b. The thickness Tdb of the first refractive layer 410 may be a distance between the upper surface of the encapsulation member 300 and the upper surface of the first refractive layer 410. The distance between the upper surface of the encapsulation member 300 and the upper surface of the second refractive pattern 415b may be substantially equal to the distance between the upper surface of the encapsulation member 300 and the upper surface of the first refractive layer 410.

As shown in FIG. 11, the first refractive layer 410 may surround each of the first refractive pattern 415a and the second refractive pattern 415b.

As shown in FIG. 12, the second opening OP2 may include a central area OPCa and a peripheral area OPPa. The central area OPCa of the second opening OP2 may be defined as an area in which the first refractive pattern 415a is arranged, and the peripheral area OPPa of the second opening OP2 may be defined as an area in which the first refractive pattern 415a is not arranged, and may be defined as an area outside the central area OPCa. As shown in FIG. 12, the third opening OP3 may include a central area OPCb and a peripheral area OPPb. The central area OPCb of the third opening OP3 may be defined as an area in which the second refractive pattern 415b is arranged, and the peripheral area OPPb of the third opening OP3 may be defined as an area in which the second refractive pattern 415b is not arranged.

A portion of the second refractive layer 420 may be arranged to fill the peripheral area OPPa of the second opening OP2. A portion of the second refractive layer 420 may be arranged to fill the peripheral area OPPa of the second opening OP2, and may surround the first refractive pattern 415a in a plan view. The first refractive layer 410 may surround a portion of the second refractive layer 420 located in the peripheral area OPPa of the second opening OP2.

A portion of the second refractive layer 420 may be arranged to fill the peripheral are OPPb of the third opening OP3. A portion of the second refractive layer 420 may be arranged to fill the peripheral area OPPb of the third opening OP3, and may surround the second refractive pattern 415b in a plan view. The first refractive layer 410 may surround a portion of the second refractive layer 420 located in the peripheral area OPPb of the third opening OP3.

In an embodiment, as shown in FIG. 11, each of the first refractive pattern 415a and the second refractive pattern 415b may surround the opening 117OP of the third insulating layer 117. However, one or more embodiments are not limited thereto. The first refractive pattern 415a may overlap the third organic light-emitting diode 200c. The second refractive pattern 415b may overlap the first organic light-emitting diode 200a. A size of each of the first refractive pattern 415a and the second refractive pattern 415b may be greater than a size of the opening 117OP of the third insulating layer 117, but is not limited thereto. In another embodiment, the size of each of the first refractive pattern 415a and the second refractive pattern 415b may be less than the size of the opening 117OP of the third insulating layer 117. In FIG. 11, a shape of each of the first refractive pattern 415a and the second refractive pattern 415b is a quadrangle. However, in another embodiment, the shape of each of the first refractive pattern 415a and the second refractive pattern 415b may be a circle, an ellipse, or a polygon, such as a triangle. The polygon may include a shape with round edges.

In case that the first refractive pattern 415a is arranged in the second opening OP2 of the first refractive layer 410 in an area overlapping the third organic light-emitting diode 200c, the thickness Ta of the second refractive layer 420 in an area overlapping the second organic light-emitting diode 200b may be greater than the thickness Tc of the second refractive layer 420 in an area overlapping the third organic light-emitting diode 200c. For example, in an area overlapping the central portion of the second organic light-emitting diode 200b, the thickness Ta of the second refractive layer 420 may be greater than the thickness Tc of the second refractive layer 420 in an area overlapping the central portion of the third organic light-emitting diode 200c. In case that the second refractive pattern 415b is arranged in the third opening OP3 of the first refractive layer 410 in an area overlapping the first organic light-emitting diode 200a, the thickness Ta of the second refractive layer 420 in an area overlapping the second organic light-emitting diode 200b may be greater than the thickness Tb of the second refractive layer 420 in an area overlapping the first organic light-emitting diode 200a. For example, the thickness Ta of the second refractive layer 420 in an area overlapping the central portion of the second organic light-emitting diode 200b may be greater than the thickness Tb of the second refractive layer 420 in an area overlapping the central portion of the first organic light-emitting diode 200a. The thickness of the second refractive layer 420 described above may be defined as an average thickness thereof in one area. The thickness Tb of the second refractive layer 420 in an area overlapping the central portion of the first organic light-emitting diode 200a may be substantially equal to the thickness Tc of the second refractive layer 420 in an area overlapping the central portion of the third organic light-emitting diode 200c. However, one or more embodiments are not limited thereto. A distance between the upper surface of the second refractive pattern 415b and the upper surface of the second refractive layer 420 may be substantially equal to a distance between the upper surface of the first refractive pattern 415a and the upper surface of the second refractive layer 420.

A lower surface of the second refractive layer 420 in an area overlapping the second organic light-emitting diode 200b may be located to be closer to the encapsulation member 300 than a lower surface of the second refractive layer 420 in an area overlapping the first organic light-emitting diode 200a. A lower surface of the second refractive layer 420 in an area overlapping the second organic light-emitting diode 200b may be located to be closer to the encapsulation member 300 than a lower surface of the second refractive layer 420 in an area overlapping the third organic light-emitting diode 200c. In an embodiment, the second refractive layer 420 may be in contact with the encapsulation member 300 in an area overlapping the second organic light-emitting diode 200b. In an embodiment, at least a portion of the second refractive layer 420 may be in contact with the second refractive pattern 415b in an area overlapping the first organic light-emitting diode 200a. In an embodiment, at least a portion of the second refractive layer 420 may be in contact with the first refractive pattern 415a in an area overlapping the third organic light-emitting diode 200c.

Each of the first refractive layer 410, the second refractive layer 420, the first refractive pattern 415a, and the second refractive pattern 415b may include a first material having a first refractive index, and a second material having a second refractive index that is lower than the first refractive index. The first material may include a light-transmitting inorganic material or organic material having a high-refractive index. The second material may include a light-transmitting inorganic material or organic material having a low-refractive index.

In an embodiment, paths of light emitted from the first and third organic light-emitting diodes 200a and 200c may be different from a path of light emitted from the second organic light-emitting diode 200b. For example, the light emitted from the first and third organic light-emitting diodes 200a and 200c may be condensed in a front direction, and the light emitted from the second organic light-emitting diode 200b may be diffused in a side direction. For example, the light emitted from the first and third organic light-emitting diodes 200a and 200c may be diffused in a side direction, and the light emitted from the second organic light-emitting diode 200b may be condensed in a front direction.

In an embodiment, the second refractive layer 420 may have a refractive index lower than a refractive index of each of the first refractive layer 410, the first refractive pattern 415a, and the second refractive pattern 415b. The paths of the light emitted from the first organic light-emitting diode 200a and the third light-emitting diode 200c may be identical or similar to the paths of the light emitted from the third organic light-emitting diode 200c described above with reference to FIGS. 9 and 10A. The light emitted from the first and third organic light-emitting diodes 200a and 200c may be condensed in a front direction, and the light emitted from the second organic light-emitting diode 200b may be diffused in a side direction.

In another embodiment, the second refractive layer 420 may have a refractive index higher than a refractive index of each of the first refractive layer 410, the first refractive pattern 415a, and the second refractive pattern 415b. The paths of the light emitted from the first organic light-emitting diode 200a and the third organic light-emitting diode 200c may be identical or similar to the paths of the light emitted from the third organic light-emitting diode 200c described with reference to FIGS. 9 and 10B. The light emitted from the first and third organic light-emitting diodes 200a and 200c may be diffused, and the light emitted from the second organic light-emitting diode 200b may be condensed in a front direction.

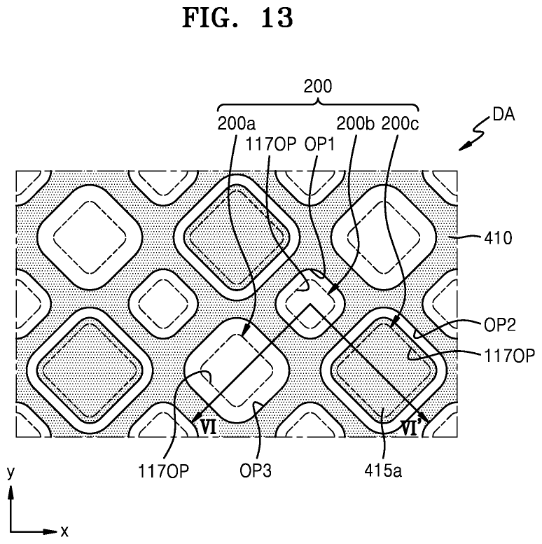

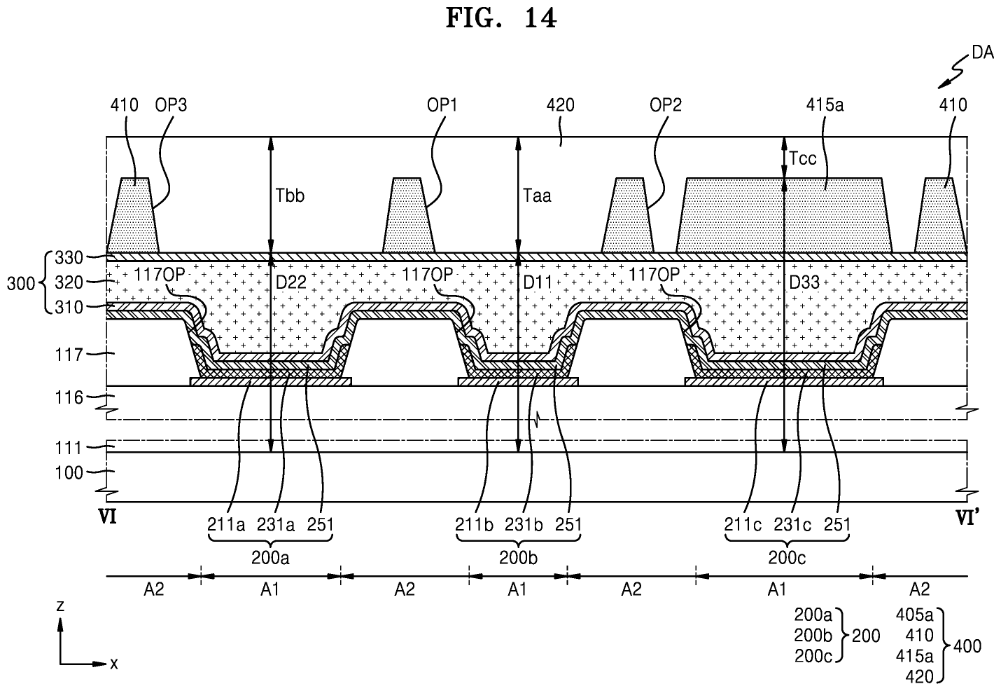

FIG. 13 is a partial schematic plan view illustrating a portion of the refractive layer 400 according to an embodiment. FIG. 14 is a schematic cross-sectional view taken along line VI-VI′ in FIG. 13. FIGS. 13 and 14 are modifications of the embodiment described with reference to FIGS. 11 and 12, redundant descriptions thereof are omitted or simplified, and differences are described.

Referring to FIGS. 13 and 14, only the second refractive layer 420 may be arranged throughout the third opening OP3, so that a path of emitted light in an area overlapping the first organic light-emitting diode 200c is not changed. For example, multiple refractive layers having different refractive indices may not be arranged in an area overlapping the organic light-emitting diodes 200a.

The refractive layer 400 may include the first refractive layer 410, the second refractive layer 420, and the first refractive pattern 415a. Each of the first refractive layer 410, the second refractive layer 420, and the first refractive pattern 415a may be formed by a photo process or an inkjet printing process. For example, the first refractive pattern 415a and the first refractive layer 410 may be formed by a photo process, and the second refractive layer 420 may be formed through an inkjet printing process.

The first refractive layer 410 may include the first opening OP1 in an area overlapping the second organic light-emitting diode 200b, may include the second opening OP2 in an area overlapping the third organic light-emitting diode 200c, and may include the third opening OP3 in an area overlapping the first organic light-emitting diode 200a.

In an embodiment, the first refractive layer 410 may not overlap the first organic light-emitting diode 200a, the second organic light-emitting diode 200b, and the third organic light-emitting diode 200c.

The first refractive pattern 415a may be arranged in the second opening OP2 of the first refractive layer 410 in an area overlapping the third organic light-emitting diode 200c. In an embodiment, only the second refractive layer 420 may be arranged in the third opening OP3 of the first refractive layer 410 in an area overlapping the first organic light-emitting diode 200a. In other words, the second refractive layer 420 may entirely fill the third opening OP3.

In case that the first refractive pattern 415a is arranged in the second opening OP2 of the first refractive layer 410 in an area overlapping the third organic light-emitting diode 200c, a thickness Taa of the second refractive layer 420 in an area overlapping the second organic light-emitting diode 200b may be greater than a thickness Tcc of the second refractive layer 420 in an area overlapping the third organic light-emitting diode 200c. For example, the thickness Taa of the second refractive layer 420 in an area overlapping the central portion of the second organic light-emitting diode 200b may be greater than the thickness Tcc of the second refractive layer 420 in an area overlapping the central portion of the third organic light-emitting diode 200c.

In case that the second refractive layer 420 fills the entire third opening OP3 of the first refractive layer 410 in an area overlapping the first organic light-emitting diode 200a, the thickness Taa of the second refractive layer 420 in an area overlapping the second organic light-emitting diode 200b may be substantially equal to the thickness Tbb of the second refractive layer 420 in an area overlapping the first organic light-emitting diode 200a. For example, the thickness Taa of the second refractive layer 420 in an area overlapping the central portion of the second organic light-emitting diode 200b may be substantially equal to the thickness Tbb of the second refractive layer 420 in an area overlapping the central portion of the first organic light-emitting diode 200a. The thickness Tbb of the second refractive layer 420 in an area overlapping the first organic light-emitting diode 200a may be greater than the thickness Tcc of the second refractive layer 420 in an area overlapping the third organic light-emitting diode 200c. For example, the thickness Tbb of the second refractive layer 420 in an area overlapping the central portion of the first organic light-emitting diode 200a may be greater than the thickness Tcc of the second refractive layer 420 in an area overlapping the central portion of the third organic light-emitting diode 200c.

In an embodiment, a distance D11 between the upper surface of the substrate 100 and a lower surface of the second refractive layer 420 in an area overlapping the second organic light-emitting diode 200b may be substantially equal to a distance D22 between the upper surface of the substrate 100 and the lower surface of the second refractive layer 420 in an area overlapping the first organic light-emitting diode 200a. For example, the distance D11 between the upper surface of the substrate 100 and the lower surface of the second refractive layer 420 in the area overlapping the second organic light-emitting diode 200b may be substantially equal to the distance D22 between the upper surface of the substrate 100 and the lower surface of the second refractive layer 420 in an area overlapping the central portion of the first organic light-emitting diode 200a. In an embodiment, the distance D11 between the upper surface of the substrate 100 and the lower surface of the second refractive layer 420 in the area overlapping the second organic light-emitting diode 200b may be less than a distance D33 between the upper surface of the substrate 100 and the lower surface of the second refractive layer 420 in an area overlapping the third organic light-emitting diode 200c. For example, the distance D11 between the upper surface of the substrate 100 and the lower surface of the second refractive layer 420 in an area overlapping the central portion of the second organic light-emitting diode 200b may be less than the distance between the upper surface of the substrate 100 and the lower surface of the second refractive layer 420 in an area overlapping the central portion of the third organic light-emitting diode 200c.

In an embodiment, because only the second refractive layer 420 overlaps in an area overlapping the first organic light-emitting diode 200a, light may be emitted in a straight line direction without being refracted. According to one or more embodiments, in case that light condensation efficiency and luminance characteristics are sufficient, a structure in which two material layers having different refractive indices in an area overlapping an organic light-emitting diode are not arranged together may be provided.

In FIG. 13, the first refractive layer 410 includes the second opening OP2 in an area overlapping the third organic light-emitting diode 200c, and the first refractive pattern 415a is arranged in the second opening OP2. However, one or more embodiments are not limited thereto. For example, an area overlapping the third organic light-emitting diode 200c may not include the second opening OP2, and may have a structure in which the second lower refractive pattern 405b is arranged between the first refractive layer 410 and the encapsulation member 300, as described with reference to FIGS. 7 to 8B.

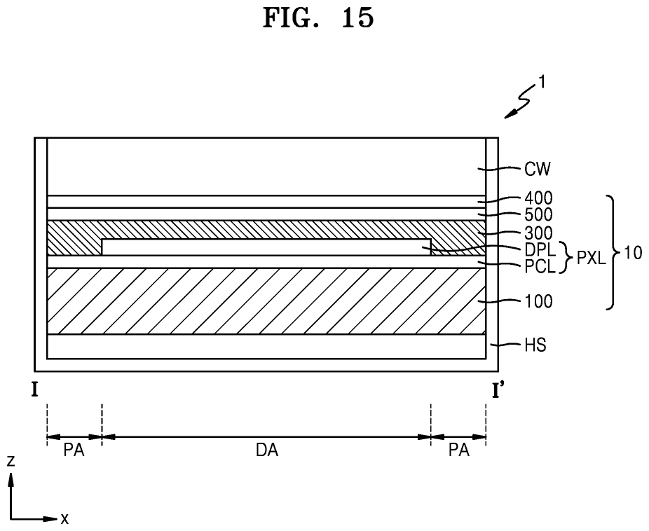

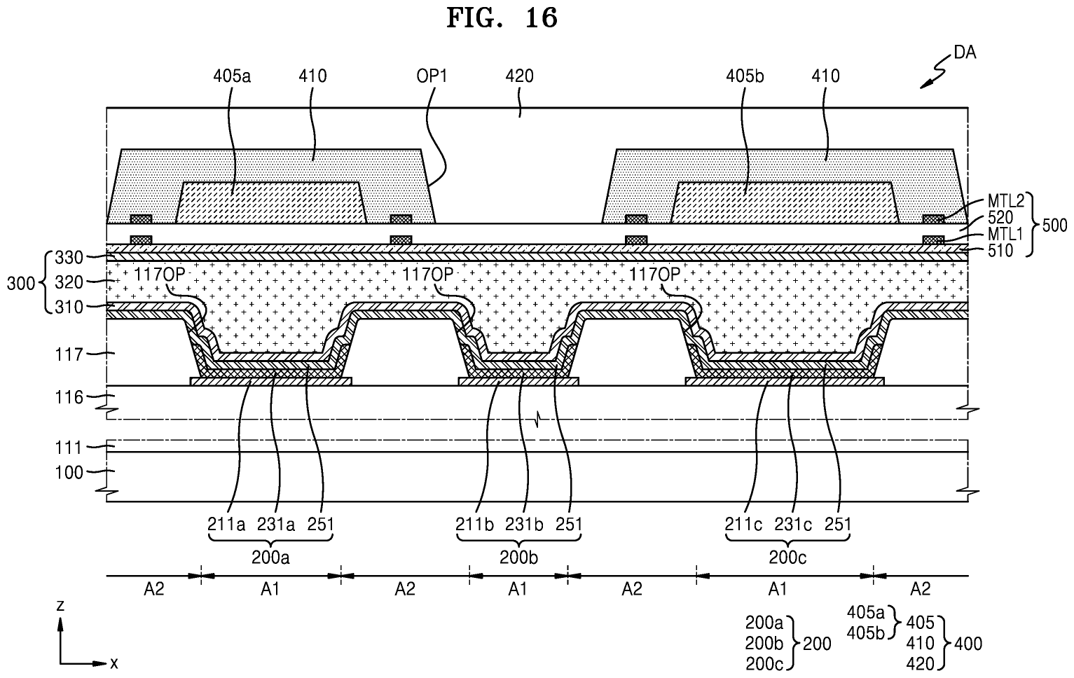

FIG. 15 is a schematic cross-sectional view taken along line I-I′ in FIG. 1, according to another embodiment. FIG. 16 is a schematic partial cross-sectional view of an electronic device according to an embodiment. A structure of the substrate 100, the pixel layer PXL, the encapsulation member 300, the refractive layer 400, the cover window CW, and the housing HS may be the same as those described above with reference to FIGS. 2 and 8A, and descriptions of same elements as those described above are omitted below.

Referring to FIGS. 15 and 16, the display panel 10 of the electronic device 1 (see FIG. 1) may further include an input sensing layer 500 between the encapsulation member 300 and the refractive layer 400. The input sensing layer 500 may be arranged between the first refractive layer 410 and the encapsulation member 300.

The input sensing layer 500 may obtain coordinate information of an external input, for example, a touch event of an object, such as a finger or a stylus pen. The input sensing layer 500 may include a sensing electrode and/or a trace line. The input sensing layer 500 may detect an external input by a mutual capacitance method or a self-capacitance method.

The input sensing layer 500 may include a first conductive layer MTL1 and a second conductive layer MTL2 each including a detection electrode and/or a trace line. A first touch insulating layer 510 may be arranged between the encapsulation member 300 and the first conductive layer MTL1, and the second touch insulating layer 520 may be arranged between the first conductive layer MTL1 and the second conductive layer MTL2. The first conductive layer MTL1 and the second conductive layer MTL2 may be arranged in the second area A2.

Each of the first conductive layer MTL1 and the second conductive layer MTL2 may include a conductive material. The conductive material may include Mo, Al, Cu, Tl, etc., and may be formed in a single layer or multiple layers including the materials described above. In some embodiments, each of the first conductive layer MTL1 and the second conductive layer MTL2 may have a structure in which a Ti layer, an aluminum layer, and a Ti layer are sequentially stacked on each other (Ti/Al/Ti).

Each of the first touch insulating layer 510 and the second touch insulating layer 520 may include an inorganic insulating material and/or an organic insulating material. The inorganic insulating material may include silicon oxide, silicon oxynitride, silicon nitride, etc. The organic insulating material may include acryl-based and imide-based organic materials.

The first refractive layer 410 of the refractive layer 400 may be disposed on the second conductive layer MTL2 and the second touch insulating layer 520. The first refractive layer 410 may be a protective layer for passivating a conductive layer of the input sensing layer 500, e.g., the second conductive layer MTL2. The second conductive layer MTL2 may be arranged to overlap the first refractive layer 410 of the refractive layer 400.

According to an embodiment, a display panel for emitting light having a uniform luminance distribution, and an electronic device including the display panel may be provided. In other embodiments, a display panel for increasing efficiency of extracted light, and an electronic device including the display panel may be provided. However, these effects are only examples, and effects according to the one or more embodiments are described in detail below.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope of the disclosure.

What is claimed is:

1. A display panel, comprising:
a pixel layer disposed on a substrate, the pixel layer including a first display element, a second display element, and a third display element, which emit light of different colors;
an encapsulation member for sealing the pixel layer;
a first refractive layer disposed on the encapsulation member and including a first opening overlapping the second display element; and
a second refractive layer disposed on the first refractive layer to overlap the first refractive layer, and having a refractive index different from a refractive index of the first refractive layer,
wherein a distance between an upper surface of the substrate and a lower surface of the second refractive layer, in an area overlapping the second display element, is smaller than a distance between the upper surface of the substrate and the lower surface of the second refractive layer, in an area overlapping the third display element.

2. The display panel of claim 1, further comprising:
a first lower refractive pattern disposed between the encapsulation member and the first refractive layer in an area overlapping the first display element,
wherein the first lower refractive pattern has a refractive index different from the refractive index of the first refractive layer.

3. The display panel of claim 2, wherein
the refractive index of the first lower refractive pattern is lower than the refractive index of the first refractive layer, and
the refractive index of the second refractive layer is lower than the refractive index of the first refractive layer.

4. The display panel of claim 2, wherein
the refractive index of the first lower refractive pattern is higher than the refractive index of the first refractive layer, and
the refractive index of the second refractive layer is higher than the refractive index of the first refractive layer.

5. The display panel of claim 2, wherein the refractive index of the first lower refractive pattern and the refractive index of the second refractive layer are equal.

6. The display panel of claim 2, further comprising a second lower refractive pattern disposed between the first refractive layer and the encapsulation member, in the area overlapping the third display element.

7. The display panel of claim 1, wherein
the first refractive layer includes a second opening in the area overlapping the third display element, and
a refractive pattern is further included in the second opening.

8. The display panel of claim 7, wherein the refractive pattern and the first refractive layer include a same material.

9. The display panel of claim 7, wherein a distance between an upper surface of the refractive pattern and an upper surface of the encapsulation member is equal to a distance between an upper surface of the first refractive layer and the upper surface of the encapsulation member.

10. The display panel of claim 7, further comprising:
a first lower refractive pattern disposed between the encapsulation member and the first refractive layer, in an area corresponding to the first display element,
wherein the first lower refractive pattern has a refractive index different from the refractive index of the first refractive layer.

11. The display panel of claim 1, wherein the first refractive layer further includes a third opening in an area corresponding to the first display element.

12. The display panel of claim 1, wherein the second refractive layer is disposed to fill the first opening of the first refractive layer.

13. The display panel of claim 1, wherein the refractive index of the second refractive layer is lower than the refractive index of the first refractive layer.

14. The display panel of claim 1, wherein the refractive index of the second refractive layer is higher than the refractive index of the first refractive layer.

15. The display panel of claim 1, further comprising:
an input sensing layer between the encapsulation member and the first refractive layer, the input sensing layer including a sensing electrode.

16. A display panel, comprising:
a pixel layer disposed on a substrate and including a display element emitting light;
an encapsulation member for sealing the pixel layer;
a first refractive layer disposed on the encapsulation member and disposed in an area overlapping the display element;
a lower refractive pattern disposed between the encapsulation member and the first refractive layer, in the area overlapping the display element, the lower refractive pattern having a refractive index different from a refractive index of the first refractive layer; and
a second refractive layer disposed on the encapsulation member to overlap the first refractive layer, the second refractive layer having a refractive index different from the refractive index of the first refractive layer.

17. The display panel of claim 16, wherein the refractive index of the lower refractive pattern is lower than the refractive index of the first refractive layer, and
the refractive index of the second refractive layer is lower than the refractive index of the first refractive layer.

18. The display panel of claim 16, wherein the refractive index of the lower refractive pattern is higher than the refractive index of the first refractive layer, and
the refractive index of the second refractive layer is higher than the refractive index of the first refractive layer.

19. The display panel of claim 16, wherein the refractive index of the lower refractive pattern and the refractive index of the second refractive layer are equal.

20. An electronic device, comprising:
a display panel;
a cover window disposed on the display panel; and
a housing accommodating the display panel and the cover window,
wherein the display panel includes:
a pixel layer disposed on a substrate, the pixel layer including a first display element, a second display element, and a third display element, which emit light of different colors;
an encapsulation member for sealing the pixel layer;
a first refractive layer disposed on the encapsulation member and including a first opening overlapping the second display element; and
a second refractive layer disposed on the first refractive layer to overlap the first refractive layer, and having a refractive index different from a refractive index of the first refractive layer,
wherein a distance between an upper surface of the substrate and a lower surface of the second refractive layer, in an area overlapping the second display element is smaller than a distance between the upper surface of the substrate and the lower surface of the second refractive layer, in an area overlapping the third display element.
